(19) United States
(12) Patent Application Publication
(10) Pub. No.: US 2025/0035708 A1
(43) Pub. Date: Jan. 30, 2025

(54) BATTERY POWER MANAGEMENT APPARATUS AND METHOD

(71) Applicant: RAYMOND ANTHONY JOAO, YONKERS, NY (US)

(72) Inventor: RAYMOND ANTHONY JOAO, YONKERS, NY (US)

(21) Appl. No.: 18/668,154

(22) Filed: May 18, 2024

Related U.S. Application Data
(60) Provisional application No. 63/529,710, filed on Jul. 29, 2023.

(51) Int. Cl. G01R 31/3842; B60L 58/12; G01R 31/36; H01M 10/42; H01M 10/48; H02J 7/00

(52) U.S. Cl. CPC G01R 31/3842; B60L 58/12; G01R 31/3647; H01M 10/482; H02J 7/0048; B60L 2240/547; B60L 2240/549; H01M 2010/4271; H01M 2220/20

(57) ABSTRACT

An apparatus, including a first circuit containing a first load; a first monitoring device which monitors a charge level of a first battery; a second circuit containing a second load; a second monitoring device which monitors a charge level of a second battery; a first switch capable of disconnecting the first battery from the first circuit; a first controller which controls the first switch; a second switch capable of connecting the first battery to the first circuit; a second controller which controls the second switch; a recharger; and a monitoring system which includes a monitoring computer. The monitoring computer detects a low charge level, generates a message, and transmits the message to a device or computer. The monitoring computer generates and issues a control signal which activates an ignition system or electric vehicle motor or propulsion system. The recharger recharges the first battery and second battery.

### RELATED APPLICATIONS

This application claims the benefit of the priority of U.S. Provisional Patent Application Ser. No. 63/529,710, filed Jul. 29, 2023, and entitled “BATTERY POWER MANAGEMENT APPARATUS AND METHOD”, the subject matter and teachings of which are hereby incorporated by reference herein in their entirety.

### FIELD OF THE INVENTION

The present invention pertains to a battery power management apparatus and method and, in particular, to a battery power management apparatus and method which can conserve battery power and/or battery charge level for electrical systems and/or components which do not require power when a vehicle, a premises, or an article, is not operating or not in use, while providing power to and/or for electrical systems and/or components which require power when the vehicle, the premises, or the article, is not operating or not in use, or which otherwise need to be provided with power when a power source and/or a battery recharging source ceases to operate or is not operational, and/or the present invention pertains to a battery power management apparatus and method which can be utilized to generate electric power so as to recharge a battery or batteries of an electric vehicle or a hybrid vehicle, of any type or kind, while the electric vehicle or the hybrid is in use or operating, as well as which can be utilized to conserve battery power and/or battery charge level for an electric vehicle or a hybrid vehicle, of any type or kind, as well as for any electrical systems and/or components of the same, which do not require power when the electric vehicle or the hybrid vehicle is not operating or not in use, while providing power to and/or for electrical systems and/or components which require power when the electric vehicle or the hybrid vehicle is not operating or not in use, or which otherwise need to be provided with power when a power source and/or a battery recharging source ceases to operate or is not operational.

### BACKGROUND OF THE INVENTION

Batteries and direct current (DC) power sources are utilized in many applications. Perhaps one of the most common uses of batteries and DC power sources is in automobiles. Typically, a vehicle battery provides the power which powers the vehicle's ignition system and a vehicle alternator generates electrical power when the vehicle's engine is operating which power can be utilized to provide the electrical power for many of a wide variety of vehicle systems, equipment systems, and/or components, along with electrical power to charge the vehicle battery.

As many who own a vehicle will readily understand, there are a number of vehicle systems, equipment systems, or components, such as, but not limited to, anti-theft systems, RF systems which operate in connection with remote control door lock openers, electronic command computers, radio clocks, and any other systems, equipment systems, or components, which require power when the vehicle is not operating, not in use, or when the engine is not operating or is not running. These vehicle systems, equipment systems, or components, which require power when the vehicle is not operating, not in use, or when the engine is not operating or is not running, presents which some may call drain or a “parasitic drain” on the vehicle battery. This drain or “parasitic drain” on the vehicle battery can deplete the vehicle's battery of its charge to a point where the battery either goes dead or does not have sufficient power to start the vehicle and/or to ensure that all vehicle systems, equipment systems, or components, are fully powered.

Disconnecting a vehicle's battery when the vehicle is not in use can serve to reserve the battery charge and/or power level, but such disconnecting of the battery deprives those vehicle systems, equipment systems, or components, which require power when the vehicle is not operating, not in use, or when the engine is not operating or is not running, of power and thereby shutting the same down. The shutting down of a vehicle's command computer, anti-theft system, radio clock, or dashboard gauges, or any other systems, equipment systems, or components, is not desirable. While vehicles are designed and built to accommodate these drains and/or “parasitic drains” on the vehicle battery when the vehicle is not operating, not in use, or when the engine is not operating or is not running, sometimes these drains or “parasitic drains” can cause a battery to lose its charge or “go dead”. Sometimes these drains are also caused by short circuits in a vehicle electric circuit, and the diagnosing and repair of same can be very time consuming and expensive.

Similar drains or “parasitic drains” can also be found in DC circuits utilized in any type or kind of vehicles, land vehicles, automobiles, trucks, recreational vehicles, boats, marine vessels, submarines, aircraft, airplanes, jets, helicopters, spacecraft, space shuttles, recreational vehicles, motorcycles, scooters, or any other type or kind of vehicle, any type or kind of premises, residential premises, commercial premises, equipment, of any system, equipment system, or component, of, in, or associated with, same, or any article which may utilize a DC power source.

Other problems can also arise when a vehicle power source or battery recharging device or source ceases to operate or is not operational, or is turned off, suddenly, unintentionally, or otherwise. For example, certain vehicles utilize alternators in order to provide power to certain of the vehicle's systems, equipment systems, devices, or components, and in order to recharge the vehicle battery, when the vehicle engine is running. The alternator might provide power to any number of vehicle systems, equipment systems, devices, or components, as well as recharge the vehicle battery when the engine is running, but the alternator stops doing so when the vehicle engine stops running or is turned off. When this occurs, those vehicle systems, equipment systems, devices, or components, which are powered by the alternator, lose power and become non-operational. These vehicle systems, equipment systems, devices, or components, can include the vehicle's power steering system, the vehicle's power brakes system, the vehicle's traction control system, the vehicle's electronic stability control system, the vehicle's anti-lock brake system, the vehicle's safety systems, the vehicle's lights, the vehicle's power door locks or vehicle power door lock systems, the vehicle's airbag systems, the vehicle's passenger restraint systems, the vehicle's supplemental restraint systems, the vehicle's communication systems, the vehicle's emergency communication systems, among others. Any loss of power to these vehicle systems, equipment systems, devices, or components can result in accidents which can cause serious injury or even death.

Similar loss of power problems can also be found in AC and/or DC circuits utilized in any type or kind of vehicles, land vehicles, automobiles, trucks, recreational vehicles, boats, marine vessels, submarines, aircraft, airplanes, jets, helicopters, spacecraft, space shuttles, recreational vehicles, motorcycles, scooters, or any other type or kind of vehicle, any type or kind of premises, residential premises, commercial premises, equipment, of any system, equipment system, or component, of, in, or associated with, same, or any article which may utilize a DC power source or battery in connection with a power source such as a generator or alternator which can provide power to certain systems, equipment systems, devices, or components, and/or which may also serve to recharge the DC power source or battery.

### SUMMARY OF THE INVENTION

The present invention pertains to a battery power management apparatus and method and, in particular, to a battery power management apparatus and method which can conserve battery power and/or battery charge level for electrical systems and/or components which do not require power when a vehicle, a premises, or an article, is not operating or not in use, while providing power to and/or for electrical systems and/or components which require power when the vehicle, the premises, or the article, is not operating or not in use, or which otherwise needs to be provided with power when a power source and/or a recharging source ceases to operate, is non-operational, or is turned off, and/or the present invention pertains to a battery power management apparatus and method which can be utilized to generate electric power so as to recharge a battery or batteries of an electric vehicle or a hybrid vehicle, of any type or kind, while the electric vehicle or the hybrid is in use or operating, as well as which can be utilized to conserve battery power and/or battery charge level for an electric vehicle or a hybrid vehicle, of any type or kind, as well as for any electrical systems and/or components of the same, which do not require power when the electric vehicle or the hybrid vehicle is not operating or not in use, while providing power to and/or for electrical systems and/or components which require power when the electric vehicle or the hybrid vehicle is not operating or not in use, or which otherwise need to be provided with power when a power source and/or a battery recharging source ceases to operate or is not operational, which overcomes the shortfalls of the prior art.

The apparatus and method of the present invention can be utilized in any number of a wide variety of applications, including but not limited to, applications in, or in connection with, motor vehicles, automobiles, trucks, mass transportation vehicles, buses, school buses, trains, subway trains, aircraft, airplanes, jets, gliders, hot air balloons, spacecraft, space shuttles, satellites, boats, marine vehicles, marine vessels, submarines, motorcycles, motor scooters, recreational vehicles (RVs) of any type or kind, mobile homes, jet skis, equipment of any kind or type, or any other vehicle (hereinafter referred to as a “vehicle” or “vehicles”), or in applications in, or in connection with, premises, residential premises, commercial premises, buildings, structures, land, or any land and/or structure of any type or kind (hereinafter referred to as a “premises” or “premises”), or in applications in, with, or in connection with, any article or device (hereinafter “article” or “articles”) which utilizes a battery or a DC power source and which is also equipped for, adapted for, or capable of, recharging that battery or DC power source. The apparatus and method of the present invention can be utilized in connection with gasoline-powered vehicles, diesel-powered vehicles, or any other fuel-powered vehicles, combustion engine powered vehicles, electric-powered vehicles, hybrid-powered vehicles, or any other types or kinds of vehicles.

The apparatus of the present invention can be utilized in, on, or in connection with, or can be adapted for and utilized in, on, or in connection with, any of the herein-identified and/or herein-defined vehicles, premises, or articles.

The apparatus includes a primary vehicle battery which can be connected to or with, or which is connectable to and/or with, the vehicle ignition system as well as any other vehicle electrical system or device or vehicle electronic system or device of the vehicle and which does not draw electrical power or current when the vehicle or the vehicle ignition system is not in use (hereafter collectively referred to as “non-drain loads”). The primary vehicle battery can be any battery or DC power source which is suitable for use in, on, or in connection with, the particular vehicle.

The primary vehicle battery can be electrically connected with, or coupled to, the vehicle ignition system in any appropriate circuit configuration, such as, but not limited to, a parallel connection or a series connection, or any combination of same, and to any number of any of the other non-drain loads in, on, or of, the vehicle in any appropriate circuit configuration, such as, but not limited to, a parallel connection or a series connection. The vehicle non-drain loads can be any electrical circuit, system, equipment system, device, or component, which requires electrical power when the vehicle, or any electrical circuit, system, equipment system, device, or component, is in use or is being operated.

The apparatus also includes a main cutoff switch which can be connected in series with the primary vehicle battery. The main cutoff switch can serve to disconnect the primary vehicle battery from all vehicle circuits and/or devices including, but not limited to, the vehicle ignition system and the vehicle non-drain loads. In this regard, the cutoff switch can be utilized to completely and electrically disconnect the primary vehicle battery from any and all loads in, on, or connected with, the vehicle.

The main cutoff switch can be a manual switch which can be placed at any suitable or convenient location in or on the vehicle and/or the main cutoff switch can also be a remotely controlled switch, such as those typically utilized in connection with remote controlled vehicle starters or remote controlled vehicle ignition systems. In this regard, a remote control device can be utilized to transmit, via a transmitter, a radio frequency (RF) signal, an infrared (IR) signal, or any other suitable signal, or communication transmission, which can be received by a corresponding receiver in, on, or at the vehicle, which can be processed by a receiver or any other appropriate controller, control device, computer, or other device, which can cause the main cutoff switch to close in order to remotely enable the vehicle to be utilized, or can cause the main cutoff switch to open so as to disable vehicle operation.

The apparatus can also include a vehicle ignition/On switch, which can be connected in series with the primary vehicle battery and which can be utilized to electrically connect or electrically disconnect the primary vehicle battery to or from each of to the vehicle ignition system and/or to or from each of any number of the non-drain loads. The vehicle ignition/On switch can also be utilized to selectively activate the vehicle ignition system in order to start the vehicle engine and/or to activate, and/or to enable an activation of, any one or more of any of the vehicles systems, equipment systems, devices, or components, and/or any vehicle non-drain loads, of the vehicle and/or to activate, and/or to enable the activation of, any one or more of the electrical circuits, systems, equipment systems, devices, or components, and/or any vehicle non-drain loads, of the vehicle which require electrical power for use or operation.

The vehicle ignition/On switch can be a manual switch, such as those which are typically utilized in connection with a vehicle key and/or the vehicle ignition/On switch can also be a remotely controlled switch, such as those typically utilized in connection with remote controlled vehicle starters or remote controlled vehicle ignition systems. In this regard, a remote control device can be utilized to transmit, via a transmitter, a radio frequency (RF) signal, an infrared (IR) signal, or any other suitable signal, or communication transmission, which can be received by a corresponding receiver in, on, or at the vehicle, which can be processed by the receiver or any other appropriate controller, control device, computer, or other device, which can cause the vehicle ignition/On switch to close in order to remotely start the vehicle's engine or can, in and under appropriate and safe circumstances, such when the vehicle engine is off, cause the vehicle ignition/On switch to open so as to disable vehicle operation.

The apparatus also includes a vehicle auxiliary battery which can be the same as, or can be of the same type or kind of battery or DC power source as the primary vehicle battery. Both of the primary vehicle battery and the vehicle auxiliary battery can be 12 volt automobile batteries, in the case where the vehicle is an automobile, which can have similar, if not identical, specifications and which can be recharged from, by, with, or using, the same electrical vehicle alternator described herein. The vehicle auxiliary battery can be connected in series or in parallel with each of all of the vehicle devices, equipment, equipment systems, or components, which typically drain current from a vehicle battery when the vehicle of the vehicle ignition systems is not operation or “off” (hereinafter collectively referred to as the “drain loads”).

The drain loads can include, for example, but are not limited to, the vehicle command computer or command computers, any computers or devices which require to be electrically powered at all times, the vehicle anti-theft system or vehicle theft-deterrent system which require to be electrically powered at all times, the remote power door locking/unlocking system and any receivers and/or computers or processing devices associated with same which require electrical power at all times, the vehicle remote starter system and any receivers and/or computers or processing devices associated with same which require electrical power at all times, the vehicle radio clock, the vehicle radio memory system, any computers or devices having or utilizing memory or any other processing capabilities which require power at all times, any gauges or associated coils which require at least some electrical power at all times to remain properly functional, and any other vehicle systems, equipment systems, components, or devices, which require electrical power at all times. In this regard, the drain loads can include, but are not limited to, a vehicle anti-theft system, a vehicle radio memory storage system or device, a radio clock, any command computer or command computers, remote door opening systems, or devices, remote control systems or devices, or any other systems, equipment systems, devices, or components, which are known to dram electrical power at all times and which can drain a vehicle battery of current and deplete its charge or charge level when a vehicle is typically not in use or is not operating.

The apparatus can also be connected to or with the vehicle alternator, which alternator is typically equipped to, and also used in order to, perform a number of functions including, but not limited to, recharging the battery of a vehicle, and which can be utilized in the apparatus of the present invention in order to continuously re-charge each of the primary vehicle battery and the vehicle auxiliary battery of the apparatus of the present invention. A single vehicle alternator can be used to recharge both the primary vehicle battery and the vehicle auxiliary battery. Two alternators can also be utilized so that one alternator can be utilized to charge the primary vehicle battery and so that the other alternator can be utilized to charge the vehicle auxiliary battery. Any pertinent circuits, components, or devices, of the alternator can be connected between each respective electrical circuit or connector(s) associated with the recharging of each of the primary vehicle battery and the vehicle auxiliary battery and a ground as needed or desired. In a preferred embodiment, the apparatus can also be connected to the ground as needed or desired.

In an embodiment in which two alternators are employed, one of the alternators can be dedicated for performing all of the functions of a typical vehicle alternator as well as, and including, recharging the primary vehicle battery and providing electrical power to the vehicle ignition system, the vehicle non-drain loads, or any electrical circuit, system, equipment system, device, or component, of the vehicle which requires electrical power when the vehicle, or any electrical circuit, system, equipment system, device, or component, is in use or is being operated, while the second alternator can be dedicated for recharging the vehicle auxiliary battery and, if needed or desired, for performing any other functions such as providing electrical power to any of the drain loads of the vehicle. In an embodiment in which two alternators are utilized, the first alternator can be connected to vehicle ground and to each of the various vehicle electrical circuits needed for providing any needed electrical power to the various electrical circuits, systems, equipment systems, devices, or components, of, in, on, or associated with, the vehicle and for recharging the primary vehicle battery, while the second alternator can be connected to vehicle ground and to any vehicle electrical circuit(s) needed for recharging the vehicle auxiliary battery as well as to any other electrical circuit(s) for which the second alternator is being utilized to supply electrical power.

The apparatus can also be utilized in order to remotely open or to remotely close each of the main cutoff switch and the vehicle ignition/On switch. In such an embodiment, the apparatus can include a transmitter, which can be any type or kind of remote control transmitter for opening or closing the circuit controlled by the main cutoff switch and which can be integrated into and/or with a vehicle remote control device, a key chain, or a key fob, or any other device, a receiver located at, in, or on, the vehicle, for receiving a signal, signals, or sequence of signals, transmitted from the transmitter and indicative of a main shutoff switch opening operation or a main cutoff switch closing operation, a controller for processing any signal, signals, or sequence of signals, received by the receiver, and an electronically activated switching device which can located in parallel with the main cutoff switch, which can serve to close or open the circuit controlled by the main cutoff switch. The electronically activated switching device can be placed in parallel with the main cutoff switch so that it can simply bypass the main cutoff switch.

The apparatus can also include a transmitter, which can be any type or kind of remote control transmitter for opening or closing the circuit controlled by the vehicle ignition/On switch and which can also be integrated into and/or with a vehicle remote control device, a key chain, or a key fob, or any other device, a receiver located at, in, or on, the vehicle, for receiving a signal, signals, or sequence of signals, transmitted from the transmitter and indicative of a vehicle ignition switch opening operation or a vehicle ignition switch closing operation, a controller for processing any signal, signals, or sequence of signals, received by the receiver, and an electronically activated switching device which can located in parallel with the vehicle ignition/On switch, which can serve to close or open the circuit controlled by the vehicle ignition/On switch. The electronically activated switching device can be placed in parallel with the vehicle ignition/On switch so that it can simply bypass the vehicle ignition/On switch.

The above-described transmitters can also be implemented by, replaced by, or used in conjunction with, a central processing computer or an Internet server which can be associated with a web site. Any authorized user or authorized person can utilize any suitable communication device, which can be a personal computer, a tablet, a tablet computer, a laptop computer, a notebook computer, a cellular telephone, a wireless telephone, a personal digital assistant, or any other suitable device, in order transmit any respective signal, signals, or sequence of signals, to a respective receiver via the central processing computer on, over, or via, the Internet and/or the World Wide Web, and/or on or over any other communication network(s), wireless communication network(s), or any combination of same. In this regard, any authorized user or authorized person can use or control the apparatus of the present invention on, over, or via, the Internet and/or the World Wide Web and/or any other communication network(s), wireless communication network(s), or any combination of same.

The apparatus of the present invention can be utilized to provide and to perform battery power management in and for any of the herein-described vehicles, premises, or articles, by providing, and/or by allowing for, the electrical powering of any electrical devices, which typically require electrical power at all times and/or when the respective vehicle, premises, or article, is not in use, while, at the same time, conserving the power of the main battery of the vehicle, the premises, or article, which is needed to activate and operate the vehicle, the premises, or the article, when same is desired to be used and/or in use.

In an embodiment wherein the main cutoff switch and the vehicle ignition switch are both in the “switch open” state or position or in the “OFF” state or position, which can be indicative of the vehicle not being in use, the primary vehicle battery can be completely disconnected from the vehicle ignition system and from the vehicle non-drain loads, which vehicle non-drain loads can be any electrical circuit, system, equipment system, device, or component, which requires electrical power when the vehicle, or any electrical circuit, system, equipment system, device, or component, is in use or is being operated. When the primary vehicle battery is completely disconnected from the vehicle ignition system and the vehicle non-drain loads, the electrical power and/or the charge level of the primary vehicle battery is conserved for later use. The apparatus provides the advantage that no electrical power is drained from the primary vehicle battery 10 when the vehicle is not operating and/or not in use, thereby conserving the charge level and the electrical power of the primary vehicle battery for later use.

The apparatus can also function as a valuable vehicle anti-theft device for the vehicle as no electrical power can be provided to the vehicle ignition system when the main cutoff switch is in the “switch open” or “OFF” sate or position. Even if one were to gain access to a vehicle key or otherwise attempt to bypass the vehicle ignition/On switch, the primary vehicle battery will remain disconnected from the vehicle ignition system and from the vehicle non-drain loads. In this manner, the apparatus of the present invention can also be utilized as a vehicle anti-theft system or device.

The vehicle auxiliary battery can provide electrical power to any and/or all of the drain loads which typically draw electrical power at all times and/or when the vehicle is in use, or operating, as well as when the vehicle is not in use or not operating. As noted above, the drain loads can include, for example, but are not limited to, the vehicle command computer or command computers, any computers or devices which require to be electrically powered at all times, the vehicle anti-theft system or vehicle theft-deterrent system which require to be electrically powered at all times, the remote power door locking/unlocking system and any receivers and/or computers or processing devices associated with same which require electrical power at all times, the vehicle remote starter system and any receivers and/or computers or processing devices associated with same which require electrical power at all times, the vehicle radio clock, the vehicle radio memory system, any computers or devices having or utilizing memory or any other processing capabilities which require power at all times, any gauges or associated coils which require at least some electrical power at all times to remain properly functional, and any other vehicle systems, equipment systems, components, or devices, which require electrical power at all times.

In this regard, the apparatus of the present invention can provide electrical power to the drain loads from the vehicle auxiliary battery while conserving the charge level and electrical power capacity of the primary vehicle battery. As noted above, the apparatus can also serve an anti-theft function and/or a theft-deterrence function for the vehicle as the primary vehicle battery is, and remains, completely disconnected from the vehicle ignition system when the main cutoff switch is in the “switch open” state or position or in the “OFF” state or position.

When the main cutoff switch is in the “switch closed” position, the primary vehicle battery can be capable of providing electrical power to the vehicle ignition system and to any of the vehicle non-drain loads described herein, and/or to any of the vehicle's systems, equipment systems, components, or devices, which can be powered by the primary vehicle battery upon, and/or subject to, the closing of the vehicle ignition/On switch.

When both the main cutoff switch and the vehicle ignition/On switch are in the “switch closed” or “ON” position, an operator can start the vehicle's engine by closing the vehicle ignition/On switch. Once the vehicle engine is running, the primary vehicle battery can provide electrical power to or for the vehicle ignition system as well as to or for to any of the vehicle non-drain loads described herein, and/or to any of the vehicle's systems, equipment systems, components, or devices.

During vehicle engine operation, the alternator or alternators, if more than one alternator is utilized, and/or any respective component(s) of the alternator or alternators can be driven by the vehicle engine in order to generate electrical power which can include both an alternating current (AC) power and a direct current (DC) power. If a single alternator is utilized, then the alternator can re-charge both the primary vehicle battery and the vehicle auxiliary battery during vehicle engine operation and can provide electrical power to or for any of the vehicle non-drain loads or drain loads described herein, and/or to any of the vehicle's systems, equipment systems, components, or devices. If two alternators are utilized, then one alternator can be connected to, and can re-charge, the primary vehicle battery, as well as provide AC and/or DC power to any of the vehicle non-drain loads described herein, and/or to any of the vehicle's systems, equipment systems, components, or devices, while the other alternator can be connected to, and can re-charge, the vehicle auxiliary battery, as well as provide AC and/or DC power to any of the vehicle's drain loads. In this regard, both the primary vehicle battery and the vehicle auxiliary battery can be re-charged during vehicle engine operation.

Use of the apparatus of the present invention can be optimized if the main cutoff switch is opened, and, therefore, placed in the “switch open” state or position or in the “OFF” state or position, immediately after the vehicle engine is turned off and thereby returned to the “switch closed” state or position or the “ON” state or position just prior to attempting to start the vehicle engine or just prior to otherwise turning the vehicle, or any vehicle system, equipment system, component, or device, “ON”, by closing the vehicle ignition/On switch, such as by switching the vehicle ignition/On switch to the “switch closed” state or position or to the “ON” state or position, or by otherwise simply turning and ignition key or pushing an ignition button or switch. In this regard, the primary vehicle battery can be “connected” when use of the vehicle, the vehicle engine, or any vehicle system, equipment system, component, or device powered by the primary vehicle battery, is desired, and the primary battery can be “disconnected” when use of the vehicle, the vehicle engine, or any vehicle system, equipment system, component, or device, which is powered by the primary vehicle battery, has ceased and/or is no longer desired. Substantial anti-theft advantages are also realized by the apparatus of the present invention as the vehicle engine will not be capable of being activated or started with the primary vehicle battery being disconnected from the vehicle ignition system.

The apparatus provides the vehicle auxiliary battery which can provide any and/or all of the vehicle drain loads with electrical power when the vehicle engine is off or not running, while preserving and/or conserving the battery charge level of the primary vehicle battery which can be completely disconnected from any electrical power or current drain loads, from the vehicle ignition system, and/or from any of the vehicle non-drain loads described herein, and/or from any of the vehicle's system, equipment systems, components, or devices. The apparatus provides a primary vehicle battery which can be completely disconnected from any load, from the vehicle ignition system, from any of the vehicle non-drain loads described herein, and/or to any of the vehicle's system, equipment systems, components, or devices, and/or from any of the vehicle drain loads, when the vehicle engine is not running, thereby maintaining a maximum charge level for the primary vehicle battery. Even if the charge level of the vehicle auxiliary battery should become depleted during a period of non-use of the vehicle engine, the primary vehicle battery can always have a sufficient charge level to start the vehicle engine and the respective vehicle alternator(s) can re-charge the vehicle auxiliary battery as well as can re-charge the primary vehicle battery.

In the manner described herein, the apparatus of the present invention provides a novel battery power management apparatus and method which can be utilized in order to provide an apparatus or system which can be utilized to ensure that a charge level of a primary vehicle battery can always be maintained, while allowing for sufficient electrical power to be provided to vehicle systems, equipment systems, components, or devices, which require and which continue to draw electrical power when the vehicle's engine is not running. In this regard, by using the apparatus of the present invention, one can ensure that any drain loads or short circuits will not cause a primary vehicle battery to be discharged or depleted of its charge and/or “go dead” while also ensuring that any and/or all vehicle systems, equipment systems, components, or devices, which require electrical power at all times and/or when the vehicle engine is not running, are provided with the electrical power needed to ensure their proper operation.

The can also include a voltage stabilizing load or resistor which can be utilized and which can be inserted between the circuit portion of the apparatus which is powered by the primary vehicle battery and the circuit portion of the apparatus which is powered by the vehicle auxiliary battery in order to connect the two circuit portions together. The resistor can be connected in between the positive sides of each of the primary vehicle battery and the vehicle auxiliary battery. With the use of the resistor, electrical power can be provided from the vehicle auxiliary battery to the vehicle ignition system and to the vehicle non-drain loads, if desired, when the vehicle ignition/On switch is in the “switch closed” state or position or in the “ON” state or position, whether or not the main cutoff switch is in the “switch closed” or “ON” state or position or in the “switch open” or “OFF” state or position. When the main cutoff switch is in the “switch closed” state or position or in the “ON” state or position, electrical power can also be provided from the primary vehicle battery to the vehicle drain loads, if desired. The resistor serves to connect the two circuit portions together while providing a stabilizing voltage drop across same in the event that the respective voltages of the primary vehicle battery and the vehicle auxiliary battery are not equal.

The apparatus and method of the present invention can also be utilized in order to provide power to any vehicle systems, equipment systems, devices, or components, in the event that the vehicle engine stops running, for any reason, which can result in the loss of the power being provided to any vehicle systems, vehicle equipment systems, devices, or components, which require power for the safe operation of the vehicle and/or for operator and/or occupant safety.

The vehicle auxiliary battery can be utilized to provide electrical power to vehicle drain/non-drain loads which can include any and/or all of the vehicle drain loads as well as any loads which can be, or which can include, any of the vehicle systems, equipment systems, devices, or components, such as, but not limited to, the vehicle's power steering system, the vehicle's power brakes system, the vehicle's traction control system, the vehicle's electronic stability control system, the vehicle's anti-lock brake system, the vehicle's safety systems, the vehicle's lights, the vehicle's power door locks or vehicle power door lock systems, the vehicle's airbag systems, the vehicle's passenger restraint systems, the vehicle's supplemental restraint systems, the vehicle's communication systems, and/or the vehicle's emergency communication systems, and/or any other load, or vehicle system, equipment system, device, or component.

Any of the vehicle drain/non-drain loads can be designed to operate on DC power in the event that the vehicle engine stops running, for any reason.

The apparatus can be designed so that the vehicle auxiliary battery can provide electrical power to any and/or all of the vehicle drain/non-drain loads which are connected to same in the event the vehicle engine stops running for any reason. In this regard, the vehicle auxiliary battery can provide power to any of the vehicle systems, equipment systems, devices, or components, in the event that the vehicle engine stops running for any reason.

The primary vehicle battery can also be utilized in order to provide electrical power to the vehicle ignition system and to any number of, or any of, the vehicle non-drain loads. The primary vehicle battery can also be utilized so as to provide electrical power only to the vehicle ignition system.

The apparatus can also be utilized in such a way so that the primary vehicle battery can provide power to the vehicle non-drain loads without providing power to the vehicle ignition system. In this manner, with the vehicle ignition/On switch in the “switch open” state or position or in the “OFF” state or position, and with the main cutoff switch in the “switch closed” state or position or the “ON” state or position, the primary vehicle battery can provide power to the vehicle non-drain loads without providing power to the vehicle ignition system.

The apparatus of the present invention can be utilized in a same, a similar, and/or an analogous, manner, as described herein, in and/or with any application involving any type or kind or vehicles, premises, or articles, which utilize rechargeable batteries to provide electrical power to any type or kind of system, equipment system, component, or device, of the respective vehicle, premises, or article, while also providing electrical power to systems, equipment systems, components, or devices, of the respective vehicle, premises, or article, which require electrical power at all times.

The apparatus and methods of the present invention can also be utilized in electric vehicles, in all-electric vehicles, and in hybrid vehicles, of any and/or all types or kinds, so as to recharge the battery, batteries, or battery pack, of the respective electric vehicle, all-electric vehicle, or hybrid vehicle, in addition to providing any and/or all of the other battery power management functions and/or functionalities described herein as being capable of being provided by apparatus and methods of the present invention. The apparatus and methods of the present invention be utilized in, or in conjunction with, any type or kind of electric, all-electric, or hybrid, vehicles, land vehicles, automobiles, buses, trains, trucks, recreational vehicles, boats, marine vessels, submarines, aircraft, airplanes, jets, helicopters, drones, spacecraft, space shuttles, recreational vehicles, motorcycles, scooters, or any other type or kind of vehicle. Any of the vehicles described herein can be manned vehicles, unmanned vehicles, and/or remote-controlled vehicles.

The apparatus and methods of the present invention can be utilized with, or in conjunction with, any rotating component, or any moving component, of any motor, motor component, electric motor, or electric motor component, transmission, transmission component, differential, differential component, axle, axle component, spindle, spindle component, reduction gear, reducer (defined herein, for purposes of this patent application, as a “type of transmission”), eaxle (defined herein, for purposes of this patent application, as a “vehicle electric drive or electric propulsion system or solution which includes or contains an electric motor, power electronics, and a transmission, for powering a vehicle's axle”), in-wheel motor, in-wheel motor component, and/or a wheel or wheel component, of any electric vehicle, any all-electric vehicle, or any hybrid vehicle, in order to drive a respective alternator or alternators, or in order to drive any generator or generators, so as to generate or produce electricity so as to re-charge the vehicle battery or vehicle batteries of the respective electric vehicle, all-electric vehicle, or hybrid vehicle.

The apparatus and/or the recharging mechanisms provided thereby can also be utilized along with remote control circuitry and/or remote control components which can be utilized in order to remotely open or to remotely close each of the main cutoff switch and the Power On switch, and/or to monitor or to control the battery power management functions or functionalities of the apparatus and methods of the present invention.

The apparatus of the present invention can also be utilized along with any number of alternators and/or generators in order to recharge the vehicle battery and the vehicle auxiliary battery.

The vehicle auxiliary battery can also be utilized to provide electrical power to the circuit portion of the apparatus which is connected to the primary vehicle battery or vehicle battery (hereinafter referred to as “primary vehicle battery 10”) while the primary vehicle battery can be utilized to provide electrical power to the circuit portion of the apparatus which is connected to the vehicle auxiliary battery.

The apparatus of the present invention can also be utilized in order to monitor the vehicle auxiliary battery of the respective apparatus and/or the state of charge of the respective vehicle auxiliary battery, to detect a low charge state of the same, and/or to effectuate the recharging of the same. The apparatus of the present invention can also be utilized in order to the monitor the respective primary vehicle battery of the respective apparatus and/or the state of charge of the respective primary vehicle battery, to detect a low charge state of the same, and/or to effectuate the recharging of the same.

The apparatus of the present invention can include a battery monitoring system for monitoring the respective vehicle auxiliary battery, for detecting a low charge state of the same, and/or for effectuating the recharging of the same. The apparatus of the present invention can also include a battery monitoring system for monitoring the respective vehicle primary battery, for detecting a low charge state of the same, and/or for effectuating the recharging of the same. A battery monitoring system or any number of battery monitoring systems can be utilized to monitor each of, or both of, the respective vehicle auxiliary battery, to detect a low charge state of the same, and/or to effectuate the recharging of the same.

The battery monitoring system can include a battery monitoring computer which includes a database. The database can store information regarding the state of charge of and for each of the respective vehicle auxiliary battery and/or the respective primary vehicle battery as well as any data and/or information needed, required, or desired for calculating, determining, or ascertaining, the state of charge of and for each of the respective vehicle auxiliary battery and/or the respective primary vehicle battery.

For each of the respective vehicle auxiliary battery and/or the respective primary vehicle battery, the database can also store data and/or information regarding the battery voltage, as well as the current flow into and/or out of, as well as the amount of charge left in, each of the respective vehicle auxiliary battery and/or the respective primary vehicle battery. For each of the respective vehicle auxiliary battery and/or the respective primary vehicle battery, the database can also store data and/or information regarding the energy that flows from or out of each of the respective vehicle auxiliary battery 60 and/or the respective primary vehicle battery.

The database can also store data and/or information regarding the low voltage limits or thresholds, or any stored value(s) which constitute or define a low voltage, or a low state of charge, of and/or for each of the respective vehicle auxiliary battery and/or the respective primary vehicle battery.

The battery monitoring system can also include a monitoring device for the vehicle auxiliary battery and a monitoring device for primary vehicle battery. Each of the monitoring device for the vehicle auxiliary battery and/or the monitoring device for the primary vehicle battery can be, or can include, any suitable battery monitoring device, and/or can be or can include any suitable or appropriate shunt-based battery monitoring device, and/or can be or can include any suitable or appropriate voltage-based battery monitoring device, and/or can be or can include any suitable or appropriate voltmeter, and/or can be or can include any suitable battery monitoring device, system, or equipment.

Each monitoring device can be, or can include, any suitable or appropriate device or equipment, any suitable or appropriate shunt-based battery monitoring device, any suitable or appropriate voltage-based battery monitoring device, any suitable or appropriate voltmeter, and/or any suitable or appropriate battery monitoring device, system, or equipment.

The battery monitoring computer can be specially programmed and/or equipped to receive, request, and/or process, data and/or information obtained by, with, or at, each monitoring device. The monitoring computer can also be specially programmed and/or equipped to process any data and/or information in order to determine a state of charge of the vehicle auxiliary battery and/or the respective primary vehicle battery, to determine a low charge state for each of the vehicle auxiliary battery and/or the respective primary vehicle battery, and/or to determine if any of the vehicle auxiliary battery and/or the respective primary vehicle battery needs to be recharged.

The battery monitoring system can also include a receiver which receives, and/or for receiving, any data and/or information transmitted by or from each the monitoring device, as well as any data, information, and/or command signals, and/or any control signals and/or monitoring signals, transmitted by or from the central processing computer, transmitted by or from the communication device of, used by, or associated with, the authorized user or authorized person of or for the vehicle, and/or transmitted by or from any other transmitter described herein.

The battery monitoring system can also include a transmitter which transmits, or for transmitting, any data and/or information, and/or commands, and/or any control signals and/or monitoring signals, to each monitoring device, as well as any data, information, and/or command signals, and/or any control signals and/or monitoring signals, to the central processing computer, to the communication device of, used by, or associated with, the authorized user or authorized person of or for the vehicle, and/or to any receiver described herein.

The battery monitoring system also includes a controller interface (I/F) for each controller described herein which provides and/or facilitates a direct electrical connection or link, for providing and/or facilitating bi-directional communication, between the battery monitoring computer, and the battery monitoring system, and the respective controller.

The apparatus of the present invention can be utilized in order to monitor the state of charge of the vehicle auxiliary battery so as to ensure that the vehicle drain loads are not in danger of being under powered or not being powered at all. The apparatus can be utilized to detect a low state of charge of or for the vehicle auxiliary battery, can generate a low state of charge alert message and can transmit the same to the communication device of, used by, or associated with, the authorized user or authorized person of or for the vehicle, and/or to the central processing computer so as to provide notification of and regarding the low state of charge of or for the vehicle auxiliary battery, and the apparatus can activate the operation of the vehicle ignition system and the alternator(s) which alternator(s) can recharge and/or at the very least maintain the charge of the vehicle auxiliary battery so as to ensure that electrical power is, and continues to be, provided to the vehicle drain loads.

The apparatus can also be utilized to monitor and detect a low state of charge of or for the primary vehicle battery, can generate a low state of charge alert message and can transmit the same to the communication device of, used by, or associated with, the authorized user or authorized person of or for the vehicle, and/or to the central processing computer so as to provide notification of and regarding the low state of charge of or for the primary vehicle battery, and the apparatus can activate the operation of the vehicle ignition system and the alternator(s) which alternator(s) can recharge and/or maintain the charge of the primary vehicle battery.

The apparatus of the present invention can also be utilized in order to monitor the state of charge of the vehicle auxiliary battery so as to ensure that the vehicle drain/non-drain loads are not in danger of being under powered or not being powered at all. The apparatus can also be utilized to detect a low state of charge of or for the vehicle auxiliary battery, can generate a low state of charge alert message and can transmit the same to the communication device of, used by, or associated with, the authorized user or authorized person of or for the vehicle, and/or to the central processing computer so as to provide notification of and regarding the low state of charge of or for the vehicle auxiliary battery, and the apparatus can activate the operation of the electric vehicle motor/propulsion/system and the alternator(s)/generator(s) which alternator(s)/generator(s) can recharge and/or at the very least maintain the charge of the vehicle auxiliary battery so as to ensure that electrical power is, and continues to be, provided to the vehicle drain/non-drain loads.

The apparatus can also be utilized to monitor and detect a low state of charge of or for the primary vehicle battery, can generate a low state of charge alert message and can transmit the same to the communication device of, used by, or associated with, the authorized user or authorized person of or for the vehicle, and/or to the central processing computer so as to provide notification of and regarding the low state of charge of or for the primary vehicle battery, and the apparatus can activate the operation of the electric vehicle motor/propulsion/system and the alternator(s)/generator(s) which alternator(s)/generator(s) can recharge and/or maintain the charge of the primary vehicle battery.

The apparatus and methods of the present invention can also be utilized in, on, and/or in connection with, and/or in conjunction with, vehicles of any kinds, types, or sizes, including, but not limited to, vehicles which require, or which may require, a driver, an operator, or a pilot, self-driving vehicles, autonomous vehicles, and/or remote-controlled vehicles, any of which vehicles can also be land vehicles, air vehicles, and/or sea vehicles or marine vehicles, of any kind, type, or size, and including, but not limited to, automobiles, cars, trucks, buses, trains, subway trains, aircraft, airplanes, jets, helicopters, drones, spacecraft, and/or satellites, and/or water vehicles or marine vehicles, boats, ships, submarines, and/or submersible vehicles, or any kind, type, or size.

In this regard, in a preferred embodiment, the apparatus and methods of the present invention can be utilized in, on, and/or in connection with, and/or in conjunction with, vehicles of any kinds, types, or sizes, including, but not limited to, vehicles which require, or which may require, a driver, an operator, or a pilot, self-driving vehicles, autonomous vehicles, and/or remote-controlled vehicles. Further, the apparatus and methods of the present invention can also be utilized in, on, and/or in connection with, and/or in conjunction with, land vehicles, air vehicles, and/or sea vehicles or marine vehicles, of any kind, type, or size. Still further, the apparatus and methods of the present invention can also be utilized in, on, and/or in connection with, and/or in conjunction with, automobiles, cars, trucks, buses, trains, subway trains, aircraft, airplanes, jets, helicopters, drones, spacecraft, and/or satellites, and/or water vehicles or marine vehicles, boats, ships, submarines, and/or submersible vehicles, or any kind, type, or size.

### BRIEF DESCRIPTION OF THE DRAWINGS

In the Drawings:

FIG. 1 illustrates a schematic diagram of a preferred embodiment of the apparatus of the present invention;

FIG. 2 illustrates another preferred embodiment of the apparatus of FIG. 1;

FIG. 3 illustrates the apparatus of FIG. 1 showing the main cutoff switch and the vehicle ignition switch both in the “switch open” state or position or in the “OFF” state or position;

FIG. 4 illustrates the apparatus of FIG. 1 showing the main cutoff switch in the “switch closed” state or position or the “ON” state or position and showing the vehicle ignition/On switch in the “switch open” state or position or in the “OFF” state or position;

FIG. 5 illustrates the apparatus of FIG. 1 showing both the main cutoff switch and the vehicle ignition/On switch in the “switch closed” state or position or in the “ON” state or position;

FIG. 6 illustrates another preferred embodiment of the apparatus of FIG. 1;

FIG. 7 illustrates still another preferred embodiment of the apparatus of FIG. 1;

FIG. 8 illustrates yet another preferred embodiment of the apparatus of FIG. 1;

FIGS. 9A, 9B, and 9C illustrate another preferred embodiment of the apparatus of the present invention;

FIGS. 10A and 10B illustrate preferred embodiment mechanism for recharging the vehicle battery and the vehicle auxiliary battery of an electric vehicle, an all-electric vehicle, and/or a hybrid vehicle;

FIG. 11 illustrates another preferred embodiment of the apparatus of the present invention;

FIG. 12 illustrates still another preferred embodiment of the apparatus of the present invention;

FIG. 13 illustrates yet another preferred embodiment of the apparatus of the present invention;

FIG. 14 illustrates another preferred embodiment of the apparatus of the present invention;

FIG. 15 illustrates still another preferred embodiment of the apparatus of the present invention;

FIG. 16 illustrates a preferred embodiment of the battery monitoring system of the apparatus of FIG. 15;

FIG. 17 illustrates another preferred embodiment of the apparatus of the present invention;

FIG. 18 illustrates a preferred embodiment method for utilizing the apparatus of FIG. 15; and

FIG. 19 illustrates a preferred embodiment method for utilizing the apparatus of FIG. 17.

### DESCRIPTION OF THE PREFERRED EMBODIMENTS

The present invention pertains to a battery power management apparatus and method and, in particular, to a battery power management apparatus and method which can conserve battery power and/or battery charge level for electrical systems and/or components which do not require power when a vehicle, a premises, or an article, is not operating or not in use, while providing power to and/or for electrical systems and/or components which require power when the vehicle, the premises, or the article, is not operating or not in use, or which otherwise needs to be provided with power when a power source and/or a recharging source ceases to operate, is non-operational, or is turned off, and/or the present invention pertains to a battery power management apparatus and method which can be utilized to generate electric power so as to recharge a battery or batteries of an electric vehicle or a hybrid vehicle, of any type or kind, while the electric vehicle or the hybrid is in use or operating, as well as which can be utilized to conserve battery power and/or battery charge level for an electric vehicle or a hybrid vehicle, of any type or kind, as well as for any electrical systems and/or components of the same, which do not require power when the electric vehicle or the hybrid vehicle is not operating or not in use, while providing power to and/or for electrical systems and/or components which require power when the electric vehicle or the hybrid vehicle is not operating or not in use, or which otherwise need to be provided with power when a power source and/or a battery recharging source ceases to operate or is not operational.

The apparatus and method of the present invention can be utilized in any number of a wide variety of applications, including but not limited to, applications in, or in connection with, motor vehicles, automobiles, trucks, mass transportation vehicles, buses, school buses, trains, subway trains, aircraft, airplanes, jets, gliders, hot air balloons, spacecraft, space shuttles, satellites, boats, marine vehicles, marine vessels, submarines, motorcycles, motor scooters, recreational vehicles (RVs) of any type or kind, mobile homes, jet skis, equipment of any kind or type, or any other vehicle (hereinafter referred to as a “vehicle” or “vehicles”), or in applications in, or in connection with, premises, residential premises, commercial premises, buildings, structures, land, or any land and/or structure of any type or kind (hereinafter referred to as a “premises” or “premises”), or in applications in, with, or in connection with, any article or device (hereinafter “article” or “articles”) which utilizes a battery or a DC power source and which is also equipped for, adapted for, or capable of, recharging that battery or DC power source. The apparatus and method of the present invention can be utilized in connection with gasoline-powered vehicles, diesel-powered vehicles, or any other fuel-powered vehicles, combustion engine powered vehicles, electric-powered vehicles, hybrid-powered vehicles, or any other types or kinds of vehicles.

The apparatus and method of the present invention can also provide a apparatus and method for remotely controlling, monitoring, and/or securing the battery power management apparatus of the present invention.

Applicant hereby incorporates by reference herein the subject matter and teachings of U.S. Provisional Patent Application Ser. No. 63/529,710, filed Jul. 29, 2023, and entitled “BATTERY POWER MANAGEMENT APPARATUS AND METHOD”, the subject matter and teachings of which are hereby incorporated by reference herein in their entirety.

Applicant hereby incorporates by reference herein the subject matter and teachings of U.S. Provisional Patent Application Ser. No. 63/149,530, filed Feb. 15, 2021, and entitled “BATTERY POWER MANAGEMENT APPARATUS AND METHOD”, the subject matter and teachings of which are hereby incorporated by reference herein in their entirety.

Applicant hereby incorporates by reference herein the subject matter and teachings of U.S. patent application Ser. No. 14/705,996, filed May 7, 2015, and entitled “BATTERY POWER MANAGEMENT APPARATUS AND METHOD”, the subject matter and teachings of which are hereby incorporated by reference herein in their entirety.

Applicant hereby incorporates by reference herein the subject matter and teachings of U.S. Provisional Patent Application Ser. No. 62/025,445, filed Jul. 16, 2014, and entitled “BATTERY POWER MANAGEMENT APPARATUS AND METHOD”, the subject matter and teachings of which are hereby incorporated by reference herein in their entirety. Applicant also hereby incorporates by reference herein the subject matter and teachings of U.S. Provisional Patent Application Ser. No. 62/018,687, filed Jun. 30, 2014, and entitled “BATTERY POWER MANAGEMENT APPARATUS AND METHOD”, the subject matter and teachings of which are hereby incorporated by reference herein in their entirety.

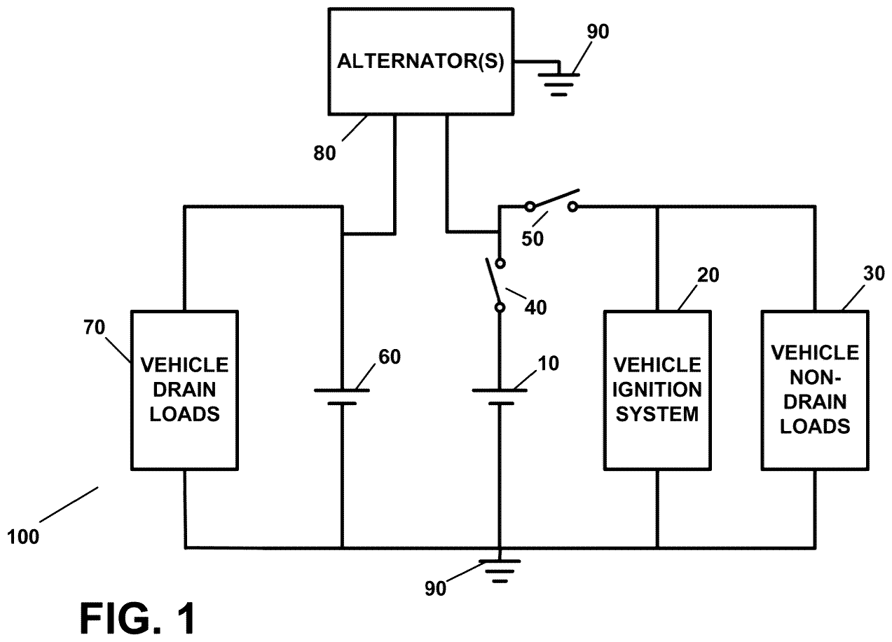

FIG. 1 illustrates a schematic diagram of a preferred embodiment of the apparatus of the present invention which is designated generally by the reference numeral 100. In a preferred embodiment, the apparatus 100 is illustrated and described as being utilized in, on, or in connection with, a motor vehicle such as, but not limited to, a car, an automobile, or a truck. Although the apparatus 100 of FIG. 1 is illustrated and described as being utilized in, on, or in connection with, a motor vehicle, it is to be understood that the apparatus 100 of the present invention can also be utilized in, on, or in connection with, or can be adapted for and utilized in, on, or in connection with, any of the herein-identified and/or herein-defined vehicles, premises, or articles.

With reference to FIG. 1, the apparatus 100, in a preferred embodiment, includes a primary vehicle battery 10 which can be connected to or with, or which is connectable to and/or with, the vehicle ignition system as well as any other vehicle electrical system or device or vehicle electronic system or device of the vehicle and which does not draw electrical power or current when the vehicle or the vehicle ignition system is not in use (hereafter collectively referred to as “non-drain loads 30”). In a preferred embodiment, the primary vehicle battery 10 can be any battery or DC power source which is suitable for use in, on, or in connection with, the particular vehicle. For example, if the vehicle is an automobile, the primary vehicle battery 10 can be any 12 Volt battery typically utilized as an automobile battery.

With reference once again to FIG. 1, the primary vehicle battery 10 can be electrically connected with, or coupled to, the vehicle ignition system 20 in any appropriate circuit configuration, such as, but not limited to, a parallel connection or a series connection, or any combination of same, and to any number of any of the other non-drain loads in, on, or of, the vehicle, which are collectively designated by the reference numeral 30 in any appropriate circuit configuration, such as, but not limited to, a parallel connection or a series connection. The vehicle non-drain loads 30 can be any electrical circuit, system, equipment system, device, or component, which requires electrical power when the vehicle, or any electrical circuit, system, equipment system, device, or component, is in use or is being operated.

In a preferred embodiment, the apparatus 100 and the circuitry of the vehicle can be designed and implemented so that the vehicle ignition system 20 and all of the vehicle non-drain loads 30, and any associated or corresponding vehicle systems, equipment systems, components, and devices, are to be provided with electrical power from the primary vehicle battery 10.

With reference once again to FIG. 1, the apparatus 100 also includes a main cutoff switch 40 which is connected in series with the primary vehicle battery, as shown. In a preferred embodiment, the main cutoff switch 40 serves to disconnect the primary vehicle battery 10 from all vehicle circuits and/or devices including, but not limited to, the vehicle ignition system 20 and the vehicle non-drain loads 30. In this regard, the cutoff switch 40 can be utilized to completely and electrically disconnect the primary vehicle battery 10 from any and all loads in, on, or connected with, the vehicle.

In a preferred embodiment, the main cutoff switch 40 can be a manual switch which can be placed at any suitable or convenient location in or on the vehicle and/or the main cutoff switch 40 can also be a remotely controlled switch, such as those typically utilized in connection with remote controlled vehicle starters or remote controlled vehicle ignition systems. In this regard, in a preferred embodiment, a remote control device can be utilized to transmit, via a transmitter, a radio frequency (RF) signal, an infrared (IR) signal, or any other suitable signal, or communication transmission, which can be received by a corresponding receiver in, on, or at the vehicle, which can be processed by a receiver or any other appropriate controller, control device, computer, or other device, which can cause the main cutoff switch 40 to close in order to remotely enable the vehicle to be utilized, or the can cause the main cutoff switch to open so as to disable vehicle operation. In FIG. 1, the main cutoff switch 40 is shown in the “switch open” or “OFF” state or position.

With reference once again to FIG. 1, the apparatus 100 also includes a vehicle ignition/On switch 50, which is connected in series with the primary vehicle battery 10, as shown, and which can be utilized to electrically connect or electrically disconnect the primary vehicle battery 10 to or from each of to the vehicle ignition system 20 and/or to or from each of any number of the non-drain loads 30. The vehicle ignition/On switch 50 can also be utilized to selectively activate the vehicle ignition system 20 in order to start the vehicle engine and/or to activate, and/or to enable an activation of, any one or more of any of the vehicles systems, equipment systems, devices, or components, and/or any vehicle non-drain loads 30, of the vehicle and/or to activate, and/or to enable the activation of, any one or more of the electrical circuits, systems, equipment systems, devices, or components, and/or any vehicle non-drain loads 30, of the vehicle which require electrical power for use or operation.

In a preferred embodiment, the vehicle ignition/On switch 50 can be a manual switch, such as those which are typically utilized in connection with a vehicle key and/or the vehicle ignition/On switch 50 can also be a remotely controlled switch, such as those typically utilized in connection with remote controlled vehicle starters or remote controlled vehicle ignition systems. In this regard in a preferred embodiment, a remote control device can be utilized to transmit, via a transmitter, a radio frequency (RF) signal, an infrared (IR) signal, or any other suitable signal, or communication transmission, which can be received by a corresponding receiver in, on, or at the vehicle, which can be processed by the receiver or any other appropriate controller, control device, computer, or other device, which can cause the vehicle ignition/On switch 50 to close in order to remotely start the vehicle's engine or can, in and under appropriate and safe circumstances, such when the vehicle engine is off, cause the vehicle ignition/On switch 50 to open so as to disable vehicle operation or vehicle engine operation. In FIG. 1, the vehicle ignition/On switch 50 is shown in the “switch open” or “OFF” state or position.

With reference once again to FIG. 1, the apparatus 100, in a preferred embodiment, also includes, a vehicle auxiliary battery 60, as shown. In a preferred embodiment, the vehicle auxiliary battery 60 can be the same as, or can be of the same type or kind of battery or DC power source as the primary vehicle battery 10. In a preferred embodiment, both of the primary vehicle battery 10 and the vehicle auxiliary battery 60 can be 12 volt automobile batteries, in the case where the vehicle is an automobile, which can have similar, if not identical, specifications and which can be recharged from, by, with, or using, the same electrical vehicle alternator described herein. The vehicle auxiliary battery 60 is connected in series or in parallel with each of all of the vehicle devices, equipment, equipment systems, or components, which typically drain current from a vehicle battery when the vehicle or the vehicle ignition system is not in operation or “off” (hereinafter collectively referred to as the “drain loads 70”).

In a preferred embodiment, the drain loads 70 can include, for example, but are not limited to, the vehicle command computer or command computers, any computers or devices which require to be electrically powered at all times, the vehicle anti-theft system or vehicle theft-deterrent system which require to be electrically powered at all times, the remote power door locking/unlocking system and any receivers and/or computers or processing devices associated with same which require electrical power at all times, the vehicle remote starter system and any receivers and/or computers or processing devices associated with same which require electrical power at all times, the vehicle radio clock, the vehicle radio memory system, any computers or devices having or utilizing memory or any other processing capabilities which require power at all times, any gauges or associated coils which require at least some electrical power at all times to remain properly functional, and any other vehicle systems, equipment systems, components, or devices, which require electrical power at all times. In this regard, the drain loads 70 can include, but are not limited to, a vehicle anti-theft system, a vehicle radio memory storage system or device, a radio clock, any command computer or command computers, remote door opening systems, or devices, remote control systems or devices, or any other systems, equipment systems, devices, or components, which are known to drain electrical power at all times and which can drain a vehicle battery of current and deplete its charge or charge level when a vehicle is typically not in use or is not operating.

In a preferred embodiment, the apparatus 100 and the circuitry of the vehicle can be designed and implemented so that the vehicle drain loads 70 and any associated or corresponding vehicle systems, equipment systems, components, and devices, are to be provided with electrical power from the vehicle auxiliary battery 60.

With reference once again to FIG. 1, the apparatus 100 can also be connected to or with the vehicle alternator 80, which alternator is typically equipped to, and also used in order to, perform a number of functions including, but not limited to, recharging the battery of a vehicle, and which can be utilized in the apparatus 100 of the present invention in order to continuously re-charge each of the primary vehicle battery 10 and the vehicle auxiliary battery 60 of the apparatus 100 of the present invention. In a preferred embodiment, a single vehicle alternator 80 can be used to recharge both the primary vehicle battery 10 and the vehicle auxiliary battery 60. In another preferred embodiment, two alternators can also be utilized so that one alternator 80 can be utilized to charge the primary vehicle battery 10 and so that the other alternator 80 can be utilized to charge the vehicle auxiliary battery 60. In a preferred embodiment, any pertinent circuits, components, or devices, of the alternator 80 can be connected between each respective electrical circuit or connector(s) associated with the recharging of each of the primary vehicle battery 10 and the vehicle auxiliary battery 60 and a vehicle ground 90 as needed or desired. In a preferred embodiment, the apparatus 100 can also be connected to the vehicle ground 90 as needed or desired.

In a preferred embodiment in which two alternators 80 are employed, one of the alternators can be dedicated for performing all of the functions of a typical vehicle alternator as well as, and including, recharging the primary vehicle battery 10 and providing electrical power to the vehicle ignition system 20, the vehicle non-drain loads 30, or any electrical circuit, system, equipment system, device, or component, of the vehicle which requires electrical power when the vehicle, or any electrical circuit, system, equipment system, device, or component, is in use or is being operated, while the second alternator can be dedicated for recharging the vehicle auxiliary battery 60 and, if needed or desired, for performing any other functions such as providing electrical power to any of the drain loads 70 of the vehicle. In an embodiment in which two alternators 80 are utilized, the first alternator 80 can be connected to vehicle ground 90 and to each of the various vehicle electrical circuits needed for providing any needed electrical power to the various electrical circuits, systems, equipment systems, devices, or components, of, in, on, or associated with, the vehicle and for recharging the primary vehicle battery 10, while the second alternator 80 can be connected to vehicle ground 90 and to any vehicle electrical circuit(s) needed for recharging the vehicle auxiliary battery 60 as well as to any other electrical circuit(s) for which the second alternator 80 is being utilized to supply electrical power.

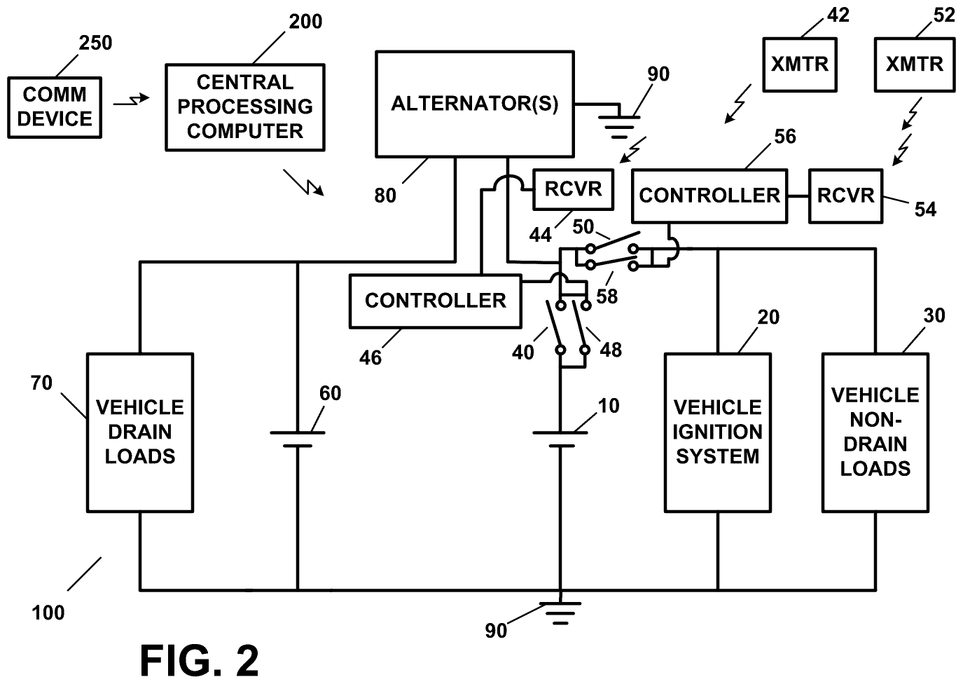

FIG. 2 illustrates another preferred embodiment of the apparatus 100 of FIG. 1. With reference to FIG. 2, the apparatus 100 includes all of the components of the apparatus 100 of FIG. 1 along with the addition of remote control circuitry and/or remote control components which can be utilized in order to remotely open or to remotely close each of the main cutoff switch 40 and the vehicle ignition/On switch 50.

With reference to FIG. 2, the apparatus 100 can include a transmitter 42, which can be any type or kind of remote control transmitter for opening or closing the circuit controlled by the main cutoff switch 40 and which, in a preferred embodiment, can be integrated into and/or with a vehicle remote control device, a key chain, or a key fob, or any other device, a receiver 44 located at, in, or on, the vehicle, for receiving a signal, signals, or sequence of signals, transmitted from the transmitter 42 and indicative of a main shutoff switch opening operation or a main cutoff switch closing operation, a controller 46 for processing any signal, signals, or sequence of signals, received by the receiver 44, and an electronically activated switching device 48 which can located in parallel with the main cutoff switch 40, which can serve to close or open the circuit controlled by the main cutoff switch 40. In a preferred embodiment, the electronically activated switching device 48 can be placed in parallel with the main cutoff switch 40 so that it can simply bypass the main cutoff switch 40 in a preferred embodiment.

With reference once again to FIG. 2, the apparatus 100 can include a transmitter 52, which can be any type or kind of remote control transmitter for opening or closing the circuit controlled by the vehicle ignition/On switch 50 and which, in a preferred embodiment, can also be integrated into and/or with a vehicle remote control device, a key chain, or a key fob, or any other device, a receiver 54 located at, in, or on, the vehicle, for receiving a signal, signals, or sequence of signals, transmitted from the transmitter 52 and indicative or a vehicle ignition switch opening operation or a vehicle ignition switch closing operation, a controller 56 for processing any signal, signals, or sequence of signals, received by the receiver 54, and an electronically activated switching device 58 which can located in parallel with the vehicle ignition/On switch 50, which can serve to close or open the circuit controlled by the vehicle ignition/On switch 50. In a preferred embodiment, the electronically activated switching device 58 can be placed in parallel with the vehicle ignition/On switch 50 so that it can simply bypass the vehicle ignition/On switch 50 in a preferred embodiment.

In a preferred embodiment, the transmitter 42 and/or the transmitter 52 can also be implemented by, replaced by, or used in conjunction with, a central processing computer or an Internet server 200 (hereinafter “central processing computer 200”), which can be associated with a web site. In another preferred embodiment, any authorized user or authorized person can utilize any suitable communication device 250, which, in a preferred embodiment, can be a personal computer, a tablet, a tablet computer, a laptop computer, a notebook computer, a cellular telephone, a wireless telephone, a personal digital assistant, or any other suitable device, in order transmit any respective signal, signals, or sequence of signals, to the respective receiver 44 and/or to the respective receiver 54 via the central processing computer 200 on, over, or via, the Internet and/or the World Wide Web, and/or on or over any other communication network(s), wireless communication network(s), or any combination of same. In this regard, in a preferred embodiment, any authorized user or authorized person can use or control the apparatus 100 of the present invention on, over, or via, the Internet and/or the World Wide Web and/or any other communication network(s), wireless communication network(s), or any combination of same.

The apparatus 100 of the present invention can be utilized in order to provide and to perform battery power management in and for any of the herein-described vehicles, premises, or articles, by providing, and/or by allowing for, the electrical powering of any electrical devices which typically require electrical power at all times and/or when the respective vehicle, premises, or article, is not operating and/or not in use, while, at the same time, conserving the power of the main battery of the vehicle, the premises, or the article, which is needed to activate and operate the vehicle, the premises, or the article, when same is desired to be used and/or in use. In a preferred embodiment, the use and operation of the apparatus 100 of the present invention can be described and illustrated in connection with use in a vehicle, such as an automobile. Although described and illustrated as being used and operated in connection with an automobile, it is important to note that the apparatus 100 can be utilized in, with, or in conjunction with, any vehicle, premises, or article.

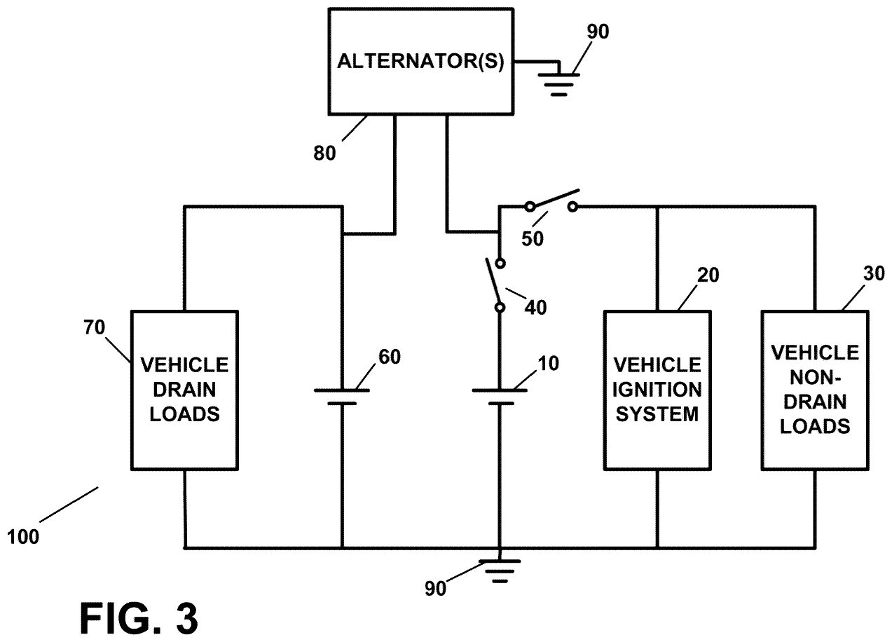

FIG. 3 illustrates the apparatus 100 of FIG. 1 showing the main cutoff switch 40 and the vehicle ignition switch 50 both in the “switch open” state or position or in the “OFF” state or position. In the embodiment of FIG. 3, which is indicative of the vehicle not being in use, the primary vehicle battery is completely disconnected from the vehicle ignition system 20 and the vehicle non-drain loads 30, which vehicle non-drain loads 30 can be any electrical circuit, system, equipment system, device, or component, which requires electrical power when the vehicle, or any electrical circuit, system, equipment system, device, or component, is in use or is being operated. When the primary vehicle battery 10 is completely disconnected from the vehicle ignition system 20 and the vehicle non-drain loads 30, as shown in FIG. 3, the electrical power and/or the charge level of the primary vehicle battery 10 is conserved for later use. The apparatus 100, when utilized as shown in FIG. 3, provides the advantage that no electrical power is drained from the primary vehicle battery 10 when the vehicle is not operating or not in use, thereby conserving the charge level and the electrical power of the primary vehicle battery 10 for later use.

The apparatus 100, when utilized as shown in FIG. 3, can also function as a vehicle anti-theft device for the vehicle as no electrical power can be provided to the vehicle ignition system 20 when the main cutoff switch is in the “switch open” or “OFF” state or position. Even if one were to gain access to a vehicle key or otherwise attempt to bypass the vehicle ignition/On switch 50, the primary vehicle battery 10 will remain disconnected from the vehicle ignition system 20 and from the vehicle non-drain loads 30 when the main cutoff switch is in the “switch open” or “OFF” state or position. In this manner, the apparatus 100 of the present invention can also be utilized as a vehicle anti-theft system or device.

With reference once again to FIG. 3, the vehicle auxiliary battery 60 provides electrical power to any and/or all of the drain loads 70 which typically draw electrical power at all times and/or when the vehicle is in use, or operating, as well as when the vehicle is not in use or not operating. As noted above, the drain loads 70 can include, for example, but are not limited to, the vehicle command computer or command computers, any computers or devices which require to be electrically powered at all times, the vehicle anti-theft system or vehicle theft-deterrent system which require to be electrically powered at all times, the remote power door locking/unlocking system and any receivers and/or computers or processing devices associated with same which require electrical power at all times, the vehicle remote starter system and any receivers and/or computers or processing devices associated with same which require electrical power at all times, the vehicle radio clock, the vehicle radio memory system, any computers or devices having or utilizing memory or any other processing capabilities which require power at all times, any gauges or associated coils which require at least some electrical power at all times to remain properly functional, and any other vehicle systems, equipment systems, components, or devices, which require electrical power at all times.

In this regard, when used as shown in FIG. 3, the apparatus 100 can serve to provide electrical power to the drain loads 70 from the vehicle auxiliary battery 60 while conserving the charge level and electrical power capacity of the primary vehicle battery 10. As noted above, the apparatus 100 of FIG. 3 also serves an anti-theft function and/or a theft-deterrence function for the vehicle as the primary vehicle battery 10 is, and remains, completely disconnected from the vehicle ignition system 20 in the embodiment of FIG. 3 when the main cutoff switch is in the “switch open” state or position or in the “OFF” state or position.

The embodiment of FIG. 3 also illustrates an exemplary embodiment wherein the apparatus 100 can be utilized to provide security against a theft or an unauthorized use of the vehicle simply by the main cutoff switch 40 being maintained in the “switch open” or “OFF” state or position.

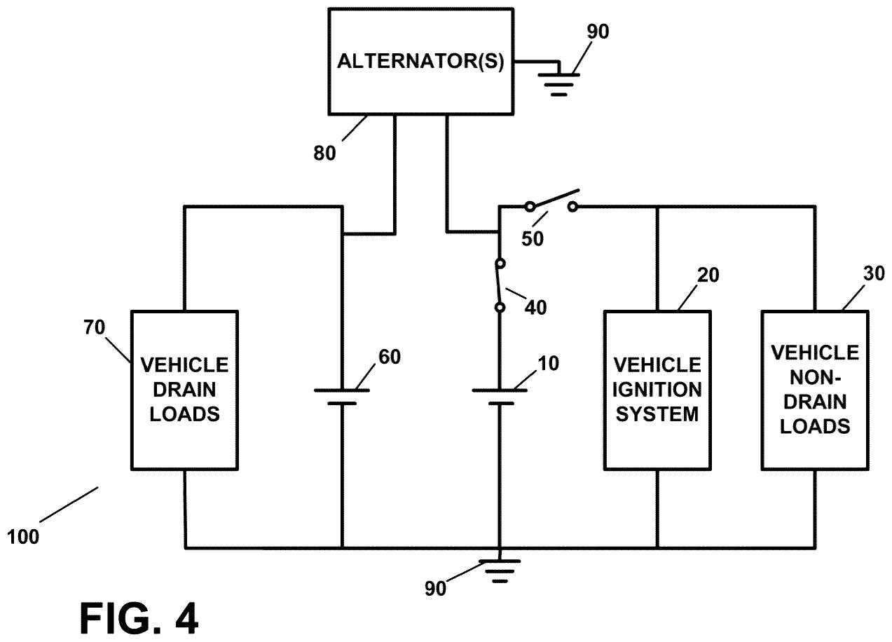

FIG. 4 illustrates the apparatus 100 of FIG. 1 showing the main cutoff switch 40 in the “switch closed” state or position or the “ON” state or position and showing the vehicle ignition/On switch 50 in the “switch open” state or position or in the “OFF” state or position. When the main cutoff switch 40 is in the “switch closed” state or position or the “ON” state or position, the primary vehicle battery 10 is capable of providing electrical power to the vehicle ignition system 20 and to any of the vehicle non-drain loads 30 described herein, and/or to any of the vehicle's systems, equipment systems, components, or devices, which can be powered by the primary vehicle battery 10, upon, and/or subject to, the closing of the vehicle ignition/On switch 50.

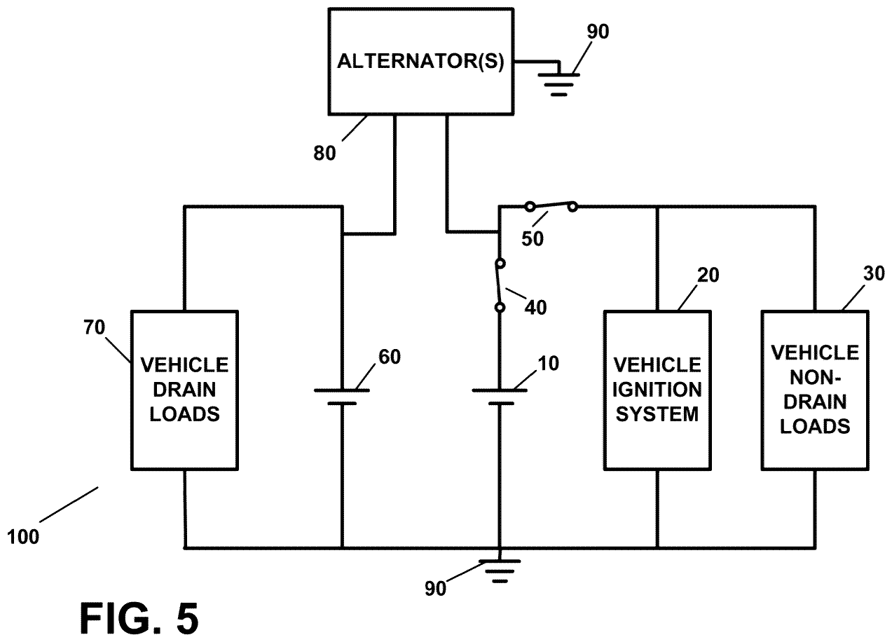

FIG. 5 illustrates the apparatus 100 of FIG. 1 showing both the main cutoff switch 40 and the vehicle ignition/On switch 50 in the “switch closed” state or position or in the “ON” state or position. With reference to FIG. 5, with the main cutoff switch 40 being closed or in the “ON” position, an operator can start the vehicle's engine by closing the vehicle ignition/On switch 50. Once the vehicle engine is running, the primary vehicle battery 10 can provide electrical power to or for the vehicle ignition system 20 as well as to or for to any of the vehicle non-drain loads 30 described herein, and/or to any of the vehicle's systems, equipment systems, components, or devices.

During vehicle engine operation, the alternator 80 or alternators 80, if more than one alternator is utilized, and/or any respective component(s) of the alternator 80 or alternators 80, will be driven by the vehicle engine in order to generate electrical power which can include both an alternating current (AC) power and a direct current (DC) power. If a single alternator 80 is utilized, then the alternator 80 will re-charge both the primary vehicle battery 10 and the vehicle auxiliary battery 60 during vehicle engine operation and will also provide electrical power to or for any of the vehicle non-drain loads 30 or drain loads 70 described herein, and/or to any of the vehicle's systems, equipment systems, components, or devices. If two alternators are utilized, then one alternator 80 can be connected to, and can re-charge, the primary vehicle battery 10, and can provide AC and/or DC power to any of the vehicle non-drain loads 30 described herein, and/or to any of the vehicle's systems, equipment systems, components, or devices, while the other alternator 80 can be connected to, and can re-charge, the vehicle auxiliary battery 60, and can provide AC and/or DC power to any of the vehicle's drain loads 70. In this regard, both the primary vehicle battery 10 and the vehicle auxiliary battery 60 can be re-charged during vehicle engine operation.

In a preferred embodiment, the apparatus 100 provides the vehicle auxiliary battery 60 which can provide any and/or all of the vehicle drain loads 70 with electrical power when the vehicle engine is off or not running, while preserving and/or conserving the battery charge level of the primary vehicle battery 10 which can be completely disconnected from any electrical power or current drain loads, from the vehicle ignition system, and/or from any of the vehicle non-drain loads 30 described herein, and/or from any of the vehicle's system, equipment systems, components, or devices. The apparatus 100 provides a primary vehicle battery 10 which can be completely disconnected from any load, from the vehicle ignition system 20, from any of the vehicle non-drain loads 30 described herein, and/or to any of the vehicle's system, equipment systems, components, or devices, and/or from any of the vehicle drain loads 70, when the vehicle engine is not running, thereby maintaining a maximum charge level for the primary vehicle battery 10. Even if the charge level of the vehicle auxiliary battery 60 should become depleted during a period of non-use of the vehicle engine, the primary vehicle battery 10 can always have a sufficient charge level to start the vehicle engine and the respective vehicle alternator(s) 80 can re-charge the vehicle auxiliary battery 60 as well as can re-charge the primary vehicle battery 10.

Use of the apparatus 100 of the present invention can be optimized if the main cutoff switch 40 is opened, and, therefore, placed in the “switch open” state or position or in the “OFF” state or position, immediately after the vehicle engine is turned off and thereby returned to the “switch closed” state or position or the “ON” state or position just prior to attempting to start the vehicle engine or just prior to otherwise turning the vehicle, or any vehicle system, equipment system, component, or device, “ON”, by closing the vehicle ignition/On switch 50, such as by switching the vehicle ignition/On switch 50 to the “switch closed” state or position or to the “ON” state or position, or by otherwise simply turning and ignition key or pushing an ignition button or switch. In this regard, the primary vehicle battery 10 can be “connected” when use of the vehicle, the vehicle engine, or any vehicle system, equipment system, component, or device powered by the primary vehicle battery, is desired, and the primary battery 10 can be “disconnected” when use of the vehicle, the vehicle engine, or any vehicle system, equipment system, component, or device, which is powered by the primary vehicle battery 10, has ceased and/or is no longer desired. Substantial anti-theft advantages are also realized by the apparatus 100 of the present invention as the vehicle engine will not be capable of being activated or started with the primary vehicle battery 10 being disconnected from the vehicle ignition system 20.

In the manner described herein, the apparatus 100 of the present invention provides a novel battery power management apparatus and method which can be utilized in order to provide an apparatus 100 or system which can be utilized to ensure that a charge level of a primary vehicle battery 10 can always be maintained, while allowing for sufficient electrical power to be provided to vehicle systems, equipment systems, components, or devices, which require and which continue to draw electrical power when the vehicle's engine is not running. In this regard, by using the apparatus 100 of the present invention, one can ensure that drain loads 70 or short circuits will not cause a primary vehicle battery 10 to discharge or to be depleted of its charge and/or “go dead” while also ensuring that any and/or all vehicle systems, equipment systems, components, or devices, which require electrical power at all times and/or when the vehicle engine is not running are provided with the electrical power needed to ensure their proper operation.

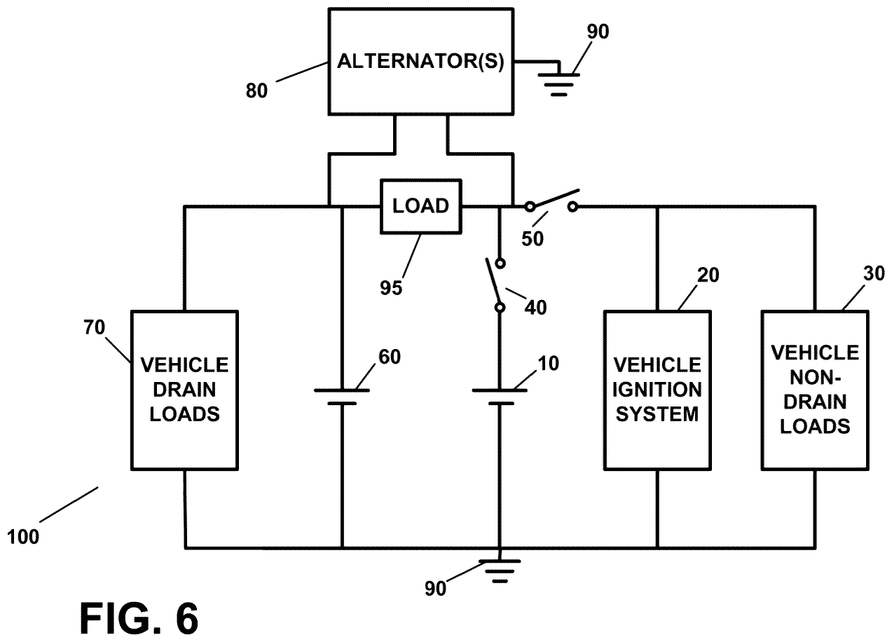

In another preferred embodiment, the vehicle auxiliary battery 60 can be utilized to provide electrical power to the circuit portion of the apparatus 100 which is connected to the primary vehicle battery 10 while the primary vehicle battery 10 can be utilized to provide electrical power to the circuit portion of the apparatus 100 which is connected to the vehicle auxiliary battery 60. FIG. 6 illustrates another preferred embodiment of the apparatus 100 of FIG. 1. In the embodiment of FIG. 6, the apparatus 100 can also include a voltage stabilizing load or resistor 95 (hereinafter “resistor 95” or “load 95”) which can be utilized and which can be inserted between the circuit portion of the apparatus 100 which is powered by the primary vehicle battery 10 and the circuit portion of the apparatus 100 which is powered by the vehicle auxiliary battery 60 in order to connect the two circuit portions together. The resistor 95 can be connected in between the positive sides of each of the primary vehicle battery 10 and the vehicle auxiliary battery 60, as shown in FIG. 6.

With the use of the resistor 95, electrical power can be provided from the vehicle auxiliary battery 60 to the vehicle ignition system 20 and to the vehicle non-drain loads 30, if desired, when the vehicle ignition/On switch 50 is in the “switch closed” state or position or in the “ON” state or position, whether or not the main cutoff switch 40 is in the “switch closed” or “ON” state or position or in the “switch open” or “OFF” state or position. When the main cutoff switch 40 is in the “switch closed” state or position or in the “ON” state or position, electrical power can also be provided from the primary vehicle battery 10 to the vehicle drain loads 70, if desired. The resistor 95 serves to connect the two circuit portions together while providing a stabilizing voltage drop across same in the event that the respective voltages of the primary vehicle battery 10 and the vehicle auxiliary battery 60 are not equal.

In another preferred embodiment, the apparatus 100 and method of the present invention can also be utilized in order to provide power to any vehicle systems, equipment systems, devices, or components, in the event that the vehicle engine stops running, for any reason, which can result in the loss of the power being provided to any vehicle systems, vehicle equipment systems, devices, or components, which require power for the safe operation of the vehicle and/or for operator and/or occupant safety.

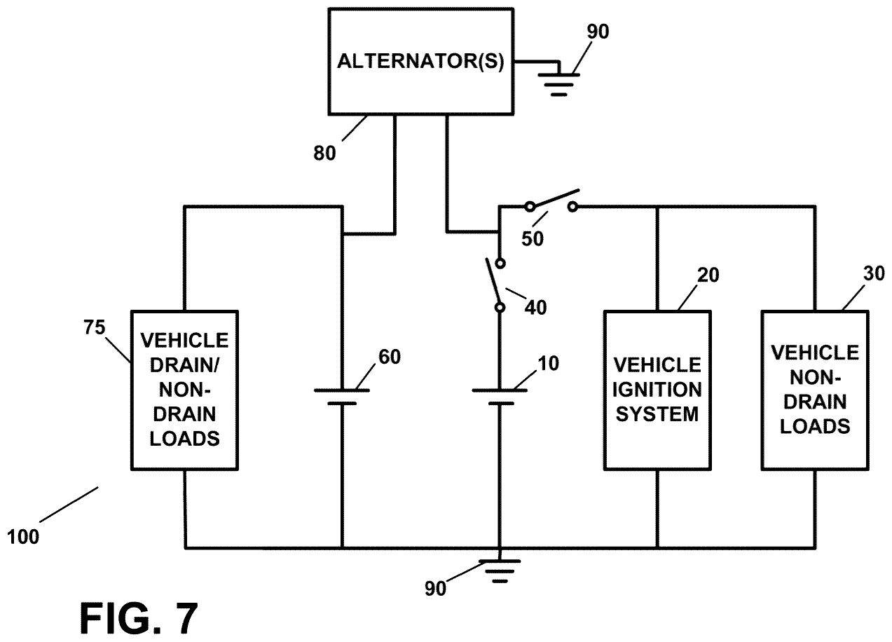

FIG. 7 illustrates another preferred embodiment of the apparatus 100 of FIG. 1. In FIG. 7, the vehicle auxiliary battery 60 provides electrical power to the vehicle drain/non-drain loads 75. In a preferred embodiment, the vehicle drain/non-drain loads 75 include any and/or all of the vehicle drain loads 70 as well as any loads which can be, or which can include any of the vehicle systems, equipment systems, devices, or components, such as, but not limited to, the vehicle's power steering system, the vehicle's power brakes system, the vehicle's traction control system, the vehicle's electronic stability control system, the vehicle's anti-lock brake system, the vehicle's safety systems, the vehicle's lights, the vehicle's power door locks or vehicle power door lock systems, the vehicle's airbag systems, the vehicle's passenger restraint systems, the vehicle's supplemental restraint systems, the vehicle's communication systems, and/or the vehicle's emergency communication systems, and/or any other load, or vehicle system, equipment system, device, or component. In a preferred embodiment, any of the vehicle drain/non-drain loads 75 can be designed to operate on DC power in the event that the vehicle engine stops running, for any reason.

With reference to FIG. 7, the apparatus 100 is designed so that the vehicle auxiliary battery 60 can provide electrical power to any and/or all of the vehicle drain/non-drain loads 75 which are connected to same in the event the vehicle engine stops running for any reason. In this regard, the vehicle auxiliary battery 60 can provide power to any of the loads, vehicle systems, equipment systems, devices, or components, in the event that the vehicle engine stops running for any reason.

In another preferred embodiment, the primary vehicle battery 10 can be utilized in order to provide electrical power to the vehicle ignition system 20 and to any number of, or any of, the vehicle non-drain loads 30. In yet another preferred embodiment, the primary vehicle battery 10 can also be utilized so as to provide electrical power only to the vehicle ignition system 20.

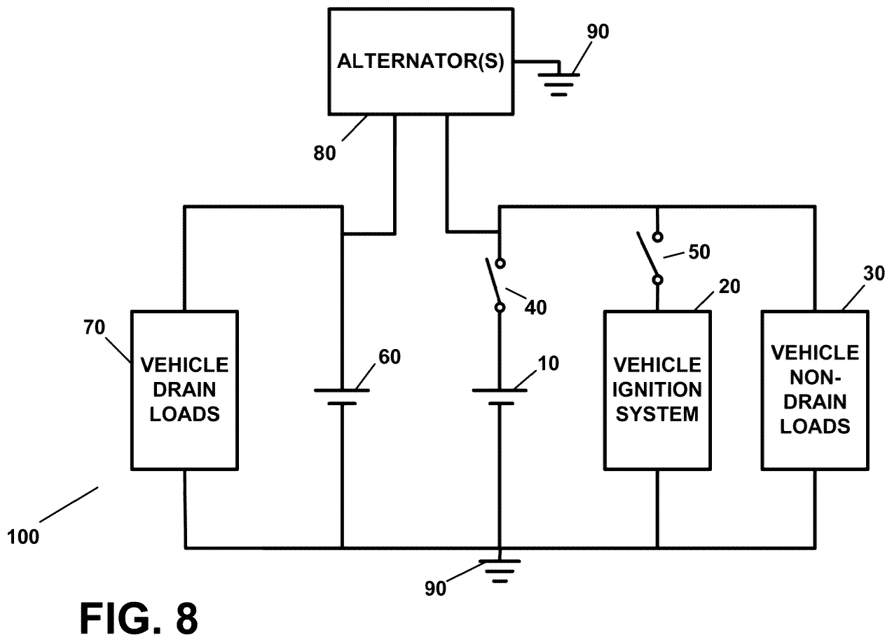

In another preferred embodiment, the apparatus 100 can also be utilized in such a way so that the primary vehicle battery 10 can provide power to the vehicle non-drain loads 30 without providing power to the vehicle ignition system 20. FIG. 8 illustrates another preferred embodiment of the apparatus 100 of FIG. 1. With reference to FIG. 8, the vehicle ignition/On switch 50 is situated at the location shown. In this manner, with the vehicle ignition/On switch 50 in the “switch open” state or position or in the “OFF” state or position, and with the main cutoff switch in the “switch closed” state or position or in the “ON” state or position, the primary vehicle battery 10 can provide power to the vehicle non-drain loads 30 without providing power to the vehicle ignition system 20.

The apparatus 100 of the present invention can be utilized in a same, a similar, and/or an analogous, manner, as described herein, in and/or with any application involving any type or kind or vehicles, premises, or articles, which utilize rechargeable batteries to provide electrical power to any type or kind of system, equipment system, component, or device, of the respective vehicle, premises, or article, while also providing electrical power to systems, equipment systems, components, or devices, of the respective vehicle, premises, or article, which require electrical power at all times.

In another preferred embodiment, as well as in any and/or all of the other embodiments described herein, the apparatus and methods of the present invention can also be utilized in electric vehicles, in all-electric vehicles, and in hybrid vehicles, of any and/or all types or kinds, so as to recharge the battery, batteries, or battery pack, of the respective electric vehicle, all-electric vehicle, or hybrid vehicle, in addition to providing any and/or all of the other battery power management functions and/or functionalities described herein as being capable of being provided by apparatus and methods of the present invention. In a preferred embodiment, the apparatus and methods of the present invention be utilized in, or in conjunction with, any type or kind of electric, all-electric, or hybrid, vehicles, land vehicles, automobiles, buses, trains, trucks, recreational vehicles, boats, marine vessels, submarines, aircraft, airplanes, jets, helicopters, drones, spacecraft, space shuttles, recreational vehicles, motorcycles, scooters, or any other type or kind of vehicle. In a preferred embodiment, any of the vehicles described herein can be manned vehicles, unmanned vehicles, and/or remote-controlled vehicles.

In a preferred embodiment, the apparatus and methods of the present invention can be utilized with, or in conjunction with, any rotating component, or any moving component, of any motor, motor component, electric motor, or electric motor component, transmission, transmission component, differential, differential component, axle, axle component, spindle, spindle component, reduction gear, reducer (defined herein, for purposes of this patent application, as a “type of transmission”), eaxle (defined herein, for purposes of this patent application, as a “vehicle electric drive or electric propulsion system or solution which includes or contains an electric motor, power electronics, and a transmission, for powering a vehicle's axle”), in-wheel motor, in-wheel motor component, and/or a wheel or wheel component, of any electric vehicle, any all-electric vehicle, or any hybrid vehicle, in order to drive a respective alternator or alternators, or in order to drive any generator or generators, so as to generate or produce electricity so as to re-charge the vehicle battery or vehicle batteries of the respective electric vehicle, all-electric vehicle, or hybrid vehicle.

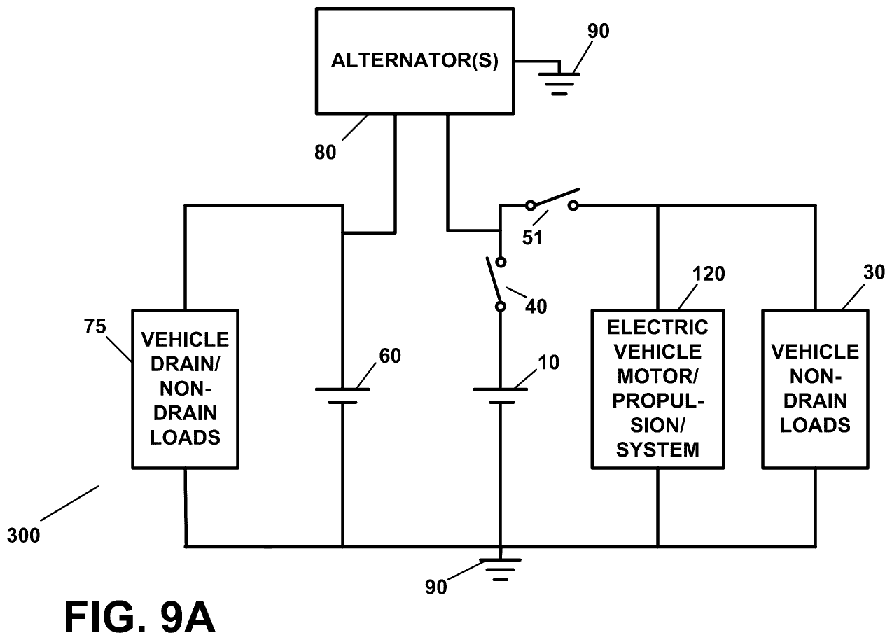

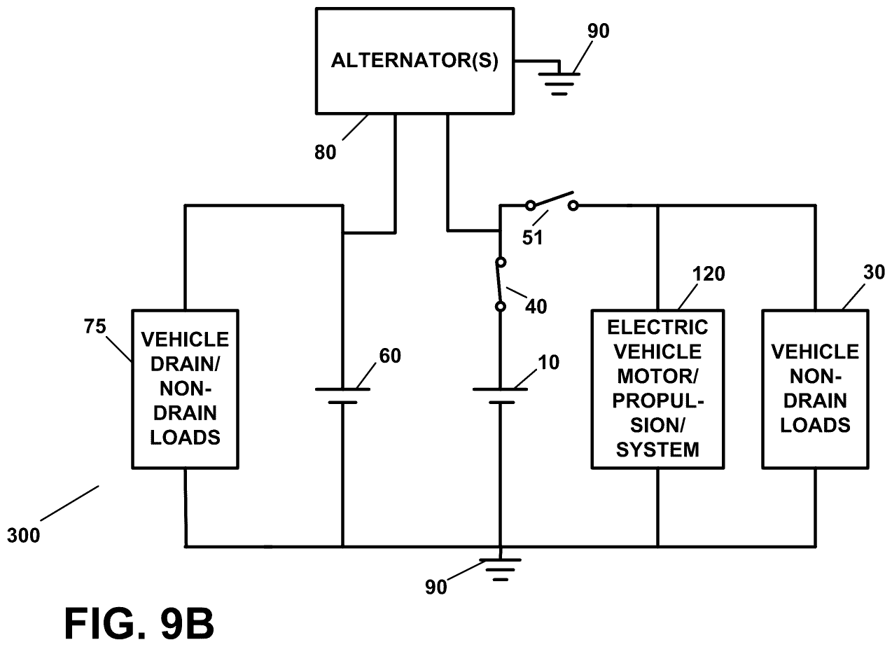

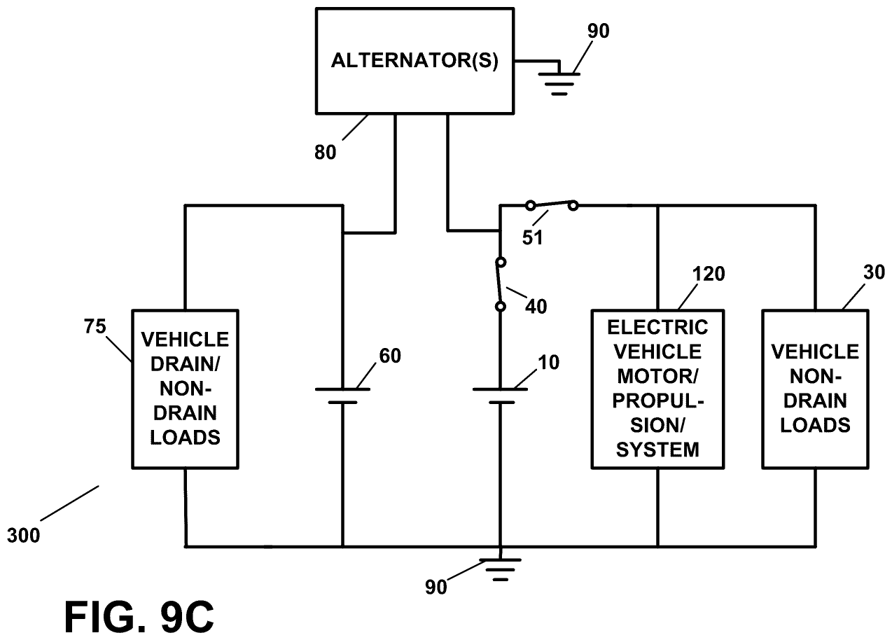

FIGS. 9A, 9B, and 9C illustrate another preferred embodiment of the present invention which can be utilized in, on, with, or in conjunction with, an electric vehicle, an all-electric vehicle, or a hybrid vehicle, so as to recharge the battery or batteries of the same and/or as well as to provide any of the herein-described battery power management functions or functionalities described herein. The apparatus of FIGS. 9A, 9B, and 9C is designated by the reference number 300. In a preferred embodiment of FIGS. 9A, 9B, and 9C, the apparatus can be utilized in, on, with, or in conjunction with, any electric vehicle, all-electric vehicle, or hybrid vehicle, of any type or kind, described herein and/or otherwise. With reference to FIGS. 9A, 9B, and 9C, the apparatus 300 includes and electric vehicle motor or propulsion system or hybrid vehicle motor or propulsion system 120 (hereinafter referred to as “electric vehicle motor/propulsion system 120”).

In a preferred embodiment, the apparatus 300 of FIGS. 9A, 9B, and 9C, with the exception of the vehicle ignition system 20 of the apparatus 100 of FIG. 7, which is replaced with the electric vehicle motor/propulsion system 120, includes all of the components of the apparatus 100 of FIG. 1. In this regard, the apparatus 300 of FIGS. 9A, 9B, and 9C includes vehicle battery 10, switch 40, Power On switch 51 (which Power On switch 51 serves an electric vehicle, all-electric vehicle, or hybrid vehicle, equivalent of, or counterpart to, a vehicle ignition/On switch 50), vehicle auxiliary battery 60, vehicle non-drain loads 30, vehicle drain/non-drain loads 75, alternator(s) 80, vehicle ground 90, and electric vehicle motor/propulsion system 120, connected and/or configured as show in each of FIGS. 9A, 9B, and 9C.

In a preferred embodiment, the electric vehicle motor/propulsion system 120 can include a vehicle electric motor or any number of vehicle electric motors, which can be used to propel or power vehicle movement or propulsion, and/or can include any combination of a vehicle electric motor or vehicle electric motors, or an in-wheel motor or in-wheel motors, and/or a transmission, a differential, an axle, a spindle, a reduction gear, a reducer (defined herein, for purposes of this patent application, as a “type of transmission”), an eaxle (defined herein, for purposes of this patent application, as a “vehicle electric drive or electric propulsion system or solution which includes or contains an electric motor, power electronics, and a transmission, for powering a vehicle's axle”), and/or a wheel, of any electric vehicle, any all-electric vehicle, or any hybrid vehicle, which can be used to power, to propel, or to facilitate the propulsion or movement of the respective electric vehicle, all-electric vehicle, or hybrid vehicle.

With reference to the FIG. 9A, the apparatus 300 is shown and illustrated with each of switch 40 and Power On switch 51 in the “OPEN” or “OFF” positions, wherein the vehicle battery 10 is disconnected from, and not capable of providing electricity to, the electric vehicle motor/propulsion system 120 and to the vehicle non-drain loads 30, and wherein the Power On switch 51 prevents any electricity from being provided, from any battery or power source, to the electric vehicle motor/propulsion system 120 and to the vehicle non-drain loads 30.

With reference to FIG. 9B, the switch 40 is shown in the “CLOSED” or “ON” position, wherein the vehicle battery 10 can be connected to, and can be capable of providing electricity to, the electric vehicle motor/propulsion system 120 and to the vehicle non-drain loads 30 if and when the Power On switch 51 is switched to the “CLOSED” or “ON” position. With reference to FIG. 9C, each of switch 40 and Power On switch 51 are shown in the “CLOSED” or “ON” positions wherein the vehicle battery 10 is connected to, and provides electricity to, the electric vehicle motor/propulsion system 120 and to the vehicle non-drain loads 30.

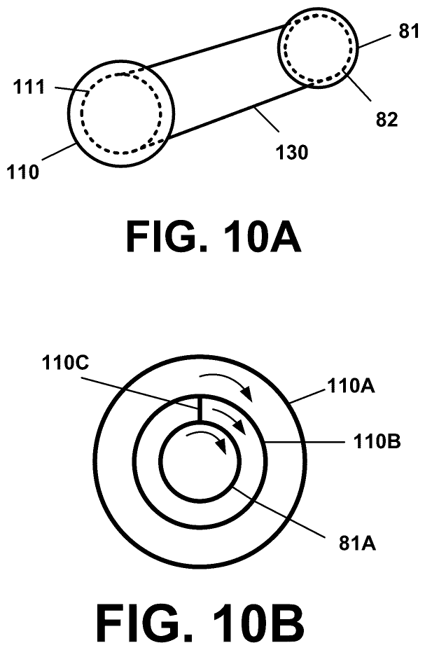

FIGS. 10A and 10B each illustrate a preferred embodiment mechanism for recharging the vehicle battery and the vehicle auxiliary battery of an electric vehicle, an all-electric vehicle, and/or a hybrid vehicle, by driving the alternator(s) 80 of the apparatus 300 with and using any suitable rotating component of a respective and suitable component of the electric vehicle motor/propulsion system 120.

FIG. 10A illustrates a preferred embodiment mechanism which includes a rotating shaft 81, which is a component of the alternator(s) 80 of FIGS. 9A, 9B, and 9C, a rotating shaft 110, which is a component of the electric vehicle motor/propulsion system 120 of FIGS. 9A, 9B, and 9C, and a fan belt 130. In a preferred embodiment, the fan belt 130 is driven by the rotating shaft 110 and, in turn, drives the rotation of the rotating shaft 81 which results in the generation of the electricity or the electrical power, by the alternator(s) 80, which electricity or electrical power is used to recharge the vehicle battery 10 and the vehicle auxiliary battery 60. In a preferred embodiment, the rotating shaft 81 provides the necessary rotation and/or rotational motion or energy which is needed by and used by the alternator(s) 80 to generate the electricity or the electrical power which is, or can be, used to recharge the vehicle battery 10 and the auxiliary vehicle battery 60 as the respective electric vehicle, all-electric vehicle, or hybrid vehicle, is operating.

With reference to FIG. 10A, the rotating shaft 81 has a recessed portion 82 (shown in dotted lines) which can facilitate a more secure seating or housing of the fan belt 130 within and/or on rotating shaft 81. As and for an example, the rotating shaft 81 can, in a preferred embodiment, be formed or molded in a cross section like a clothesline pulley so that the fan belt 130 can be situated between the sidewalls of the same in and during operation. With reference to FIG. 10A, the rotating shaft 110 also has a recessed portion 111 (shown in dotted lines) which can also facilitate a more secure seating or housing of the fan belt 130 within and/or on the rotating shaft 110. As and for an example, the rotating shaft 110 can, in a preferred embodiment, also be formed or molded in a cross section like a clothesline pulley so that the fan belt 130 can be situated between the sidewalls of the same in and during operation. In a preferred embodiment, the fan belt 130 should be secured tightly about the between the rotating shaft 81 and the rotating shaft 110 so as to prevent slippage of the fan belt 130, and so as to ensure that the rotational energy of the rotating shaft 110 is transferred to the rotating shaft 81 in an optimal and efficient manner.

In a preferred embodiment, the fan belt 130, which is utilized in the apparatus of FIGS. 9A, 9B, 9C, and 10A, can be of the type or kind which is similar to, or analogous to, conventional vehicle fan belts which are used to drive alternators or air conditioner system components in internal combustion engine vehicles. In another preferred embodiment, the fan belt 130, and/or the recessed portions 82, of the rotating shaft 81, and the recessed portions 111, of the rotating shafts 110, can be provided with corresponding grooves, serrations, or other traction inducing formations, which can prevent slippage of the fan belt 130. In another preferred embodiment, the fan belt 130 can be implemented with a chain of metal, plastic, or any other suitable material, and the the recessed portions 82, of the rotating shaft 81, and the recessed portions 111, of the rotating shafts 110, can be provided with corresponding sprocket-like protrusions (in a manner similar to a bicycle chain and sprocket system) in order to prevent slippage of the fan belt 130 on or about the rotating shaft 81 and or the rotating shaft 110.

With reference to FIG. 10A, once the fan belt 130 is adequately secured about both the rotating shaft 110 and the rotating shaft 81, the rotation of the rotating shaft 110 will drive the rotation of the rotating shaft 81.

In a preferred embodiment, any suitable and/or appropriate design technique(s) can be utilized to provide the rotating shaft 81 and the rotating shaft 110 of FIG. 10A so that the fan belt 130, which is to be driven by the rotating shaft 110, which is a rotating component of the electric vehicle motor/propulsion system 120 or any suitable component of same, can drive the rotation of the rotating shaft 81.

In a preferred embodiment, the rotating shaft 110 can be a component of any suitable component of the electric vehicle motor/propulsion system 120. In a preferred embodiment, the rotating shaft 110 can be a component of a vehicle electric motor, an in-wheel motor, a transmission, a differential, an axle, a spindle, a reduction gear, a reducer, an eaxle, or a wheel, of the respective electric vehicle, all-electric vehicle, or hybrid vehicle. In a preferred embodiment, the rotating shaft 110 can be a component of a vehicle electric motor or an in-wheel motor. In another preferred embodiment, the rotating shaft 110 can be a component of a transmission. In another preferred embodiment, the rotating shaft 110 can be a component of a differential. In another preferred embodiment, the rotating shaft 110 can be a component of an axle. In another preferred embodiment, the rotating shaft 110 can be a component of a spindle. In another preferred embodiment, the rotating shaft 110 can be a component of a reduction gear. In another preferred embodiment, the rotating shaft 110 can be a component of a reducer. In another preferred embodiment, the rotating shaft 110 can be a component of an eaxle. In another preferred embodiment, the rotating shaft 110 can be a component of a wheel. In another preferred embodiment, the rotating shaft 110 can be any rotating component of the respective electric vehicle, all-electric vehicle, or hybrid vehicle.

In another preferred embodiment, for any single electric vehicle, all-electric vehicle, or hybrid vehicle, any number of rotating shafts 81, rotating shafts 110, and fan belts 130, can be utilized or employed in, on, with, or in conjunction with, any number of multiple components of the electric vehicle motor/propulsion system 120 of the respective electric vehicle, all-electric vehicle, or hybrid vehicle, and/or any number of rotating shafts 81, rotating shafts 110, and fan belts 130, can be utilized or employed at multiple locations of, in, on, with, or in conjunction with, any one or single rotating component of the electric vehicle motor/propulsion system 120 of the respective electric vehicle, all-electric vehicle, or hybrid vehicle.

With reference once again to FIG. 10A, the mechanism disclosed therein can be used to generate electricity or electrical power in the following manner. When the electric vehicle motor/propulsion system is operating and/or when the vehicle is in motion, the rotation of the rotating shaft 110 (of the respective component of the electric vehicle motor/propulsion system 120) will, via the fan belt 130, drive the rotation of the rotating shaft 81. The rotation of the rotating shaft 81 will drive the alternator(s) 80 and the alternator(s) 80 will generate electricity which is used to recharge the vehicle battery 10 and the vehicle auxiliary battery 60.

FIG. 10B illustrates a cross section of another preferred embodiment mechanism for driving a rotating shaft of the alternator(s) 80 so as to generate electricity which is used to recharge the vehicle battery 10 and the vehicle auxiliary battery 60. With reference to FIG. 10B, the rotating shaft 81A, which is a component of the alternator(s) 80, is shown situated coaxially within the rotating shaft 110A of the respective component of the electric vehicle motor/propulsion system 120. With reference to FIG. 10B, the rotating shaft 110A has an inner surface 110B as shown. In a preferred embodiment, the rotating shaft 81A is fastened to the inner surface 110B of the rotating shaft 110A via connecting member 110C as shown. In the mechanism of FIG. 10B, as the rotating shaft 110A rotates, the connecting member 110C causes the rotating shaft 81A to rotate in the same direction as the rotation of the rotating shaft 110A. Although shown as rotating clockwise, it is important to note that rotating shaft 110A can also rotate counterclockwise, and when such is the case, the rotating shaft 81A would also rotate counterclockwise along with the rotating shaft 110C.

With reference once again to FIG. 10B, the mechanism disclosed therein can be used to generate electricity or electrical power in the following manner. When the electric vehicle motor/propulsion system is operating and/or when the vehicle is in motion, the rotation of the rotating shaft 110A (of the respective component of the electric vehicle motor/propulsion system 120) will, via the connecting member 110C, drive the rotation of the rotating shaft 81A. The rotation of the rotating shaft 81A will drive the alternator(s) 80 and the alternator(s) 80 will generate electricity which is used to recharge the vehicle battery 10 and the vehicle auxiliary battery 60.

In another preferred embodiment, the apparatus 300 and/or the recharging mechanisms of FIGS. 10A and/or 10B can also be utilized along with remote control circuitry and/or remote control components which can be utilized in order to remotely open or to remotely close each of the main cutoff switch 40 and the Power On switch 51, and/or to monitor or to control the battery power management functions or functionalities of the apparatus and methods of the present invention.

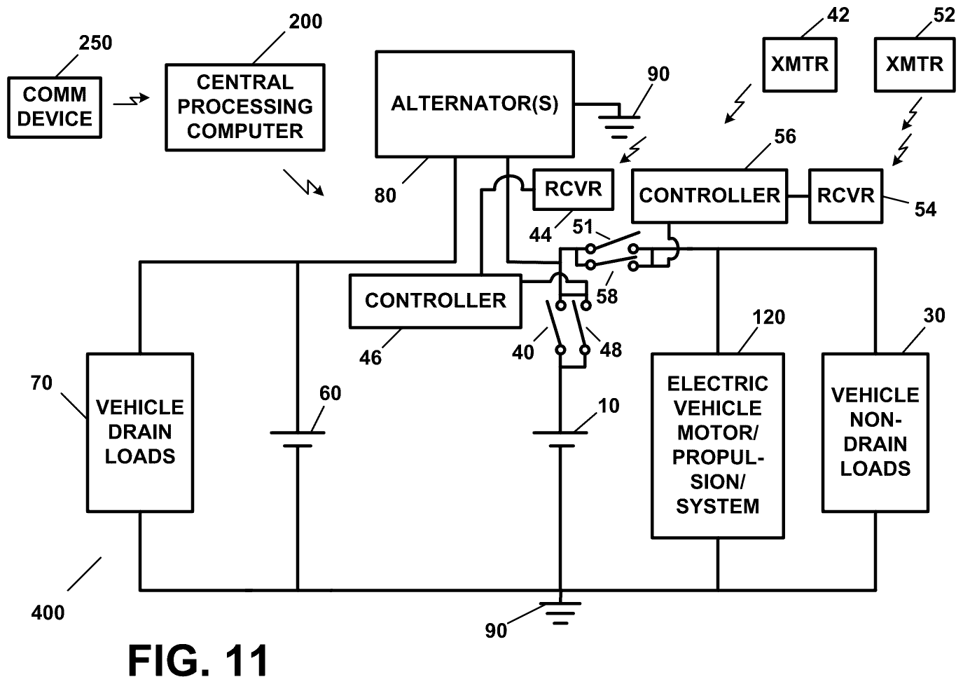

FIG. 11 illustrates another preferred embodiment of the apparatus of the present invention which is designated by the reference number 400. With reference to FIG. 11, the apparatus 400 includes, in place of a vehicle ignition system 20, an electric vehicle motor/propulsion system 120. With reference to FIG. 11, the apparatus 400 can include a transmitter 42, which can be any type or kind of remote control transmitter for opening or closing the circuit controlled by the main cutoff switch 40 and which, in a preferred embodiment, can be integrated into and/or with a vehicle remote control device, a key chain, or a key fob, or any other device, a receiver 44 located at, in, or on, the vehicle, for receiving a signal, signals, or sequence of signals, transmitted from the transmitter 42 and indicative of a main shutoff switch opening operation or a main cutoff switch closing operation, a controller 46 for processing any signal, signals, or sequence of signals, received by the receiver 44, and an electronically activated switching device 48 which can located in parallel with the main cutoff switch 40, which can serve to close or open the circuit controlled by the main cutoff switch 40. In a preferred embodiment, the electronically activated switching device 48 can be placed in parallel with the main cutoff switch 40 so that it can simply bypass the main cutoff switch 40 in a preferred embodiment.

With reference once again to FIG. 11, the apparatus 400 can include a transmitter 52, which can be any type or kind of remote control transmitter for opening or closing the circuit controlled by the Power On switch 51 and which, in a preferred embodiment, can also be integrated into and/or with a vehicle remote control device, a key chain, or a key fob, or any other device, a receiver 54 located at, in, or on, the vehicle, for receiving a signal, signals, or sequence of signals, transmitted from the transmitter 52 and indicative or a vehicle Power On switch 51 opening operation or a Power On switch 51 closing operation, a controller 56 for processing any signal, signals, or sequence of signals, received by the receiver 54, and an electronically activated switching device 58 which can located in parallel with the Power On switch 51, which can serve to close or open the circuit controlled by the Power On switch 51. In a preferred embodiment, the electronically activated switching device 58 can be placed in parallel with the Power On switch 51 so that it can simply bypass the Power On switch 51 in a preferred embodiment.

In a preferred embodiment, the transmitter 42 and/or the transmitter 52 can also be implemented by, replaced by, or used in conjunction with, a central processing computer or an Internet server 200 (hereinafter “central processing computer 200”), which can be associated with a web site. In another preferred embodiment, any authorized user or authorized person can utilize any suitable communication device 250, which, in a preferred embodiment, can be a personal computer, a tablet, a tablet computer, a laptop computer, a notebook computer, a cellular telephone, a wireless telephone, a personal digital assistant, or any other suitable device, in order transmit any respective signal, signals, or sequence of signals, to the respective receiver 44 and/or to the respective receiver 54 via the central processing computer 200 on, over, or via, the Internet and/or the World Wide Web, and/or on or over any other communication network(s), wireless communication network(s), or any combination of same. In this regard, in a preferred embodiment, any authorized user or authorized person can use or control the apparatus 100 of the present invention on, over, or via, the Internet and/or the World Wide Web and/or any other communication network(s), wireless communication network(s), or any combination of same.

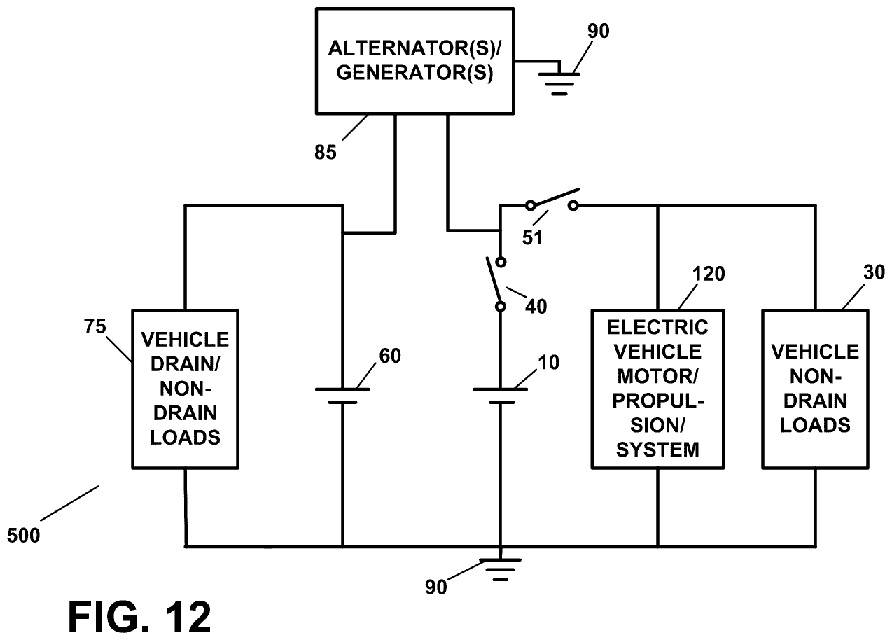

In another preferred embodiment, the apparatus 300 of FIGS. 9A, 9B, and 9C can also be utilized along with any number of alternators and/or generators in order to recharge the vehicle battery 10 and the vehicle auxiliary battery 60. FIG. 12 illustrates another preferred embodiment of the apparatus of the present invention which is designated by the reference numeral 500. With reference to FIG. 12, the apparatus 500 includes, in place of alternator(s) 80, alternator(s)/generators 85.

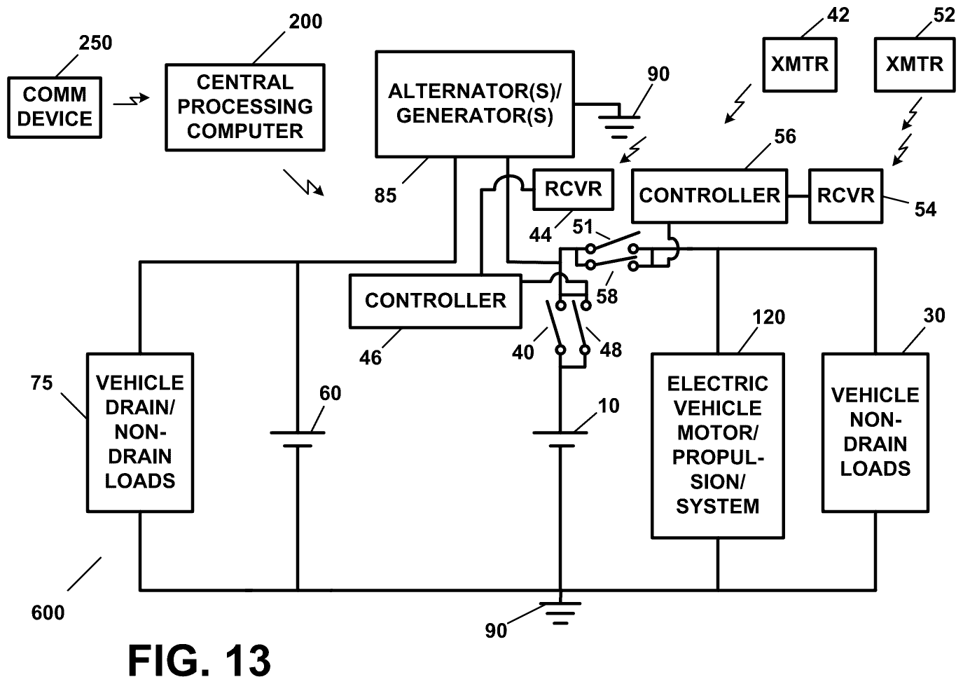

In another preferred embodiment, the apparatus 400 of FIG. 11 can also be utilized along with any number of alternators and/or generators in order to recharge the vehicle battery 10 and the vehicle auxiliary battery 60. FIG. 13 illustrates another preferred embodiment of the apparatus of the present invention which is designated by the reference numeral 600. With reference to FIG. 13, the apparatus 600 includes, in place of alternator(s) 80, alternator(s)/generators 85.

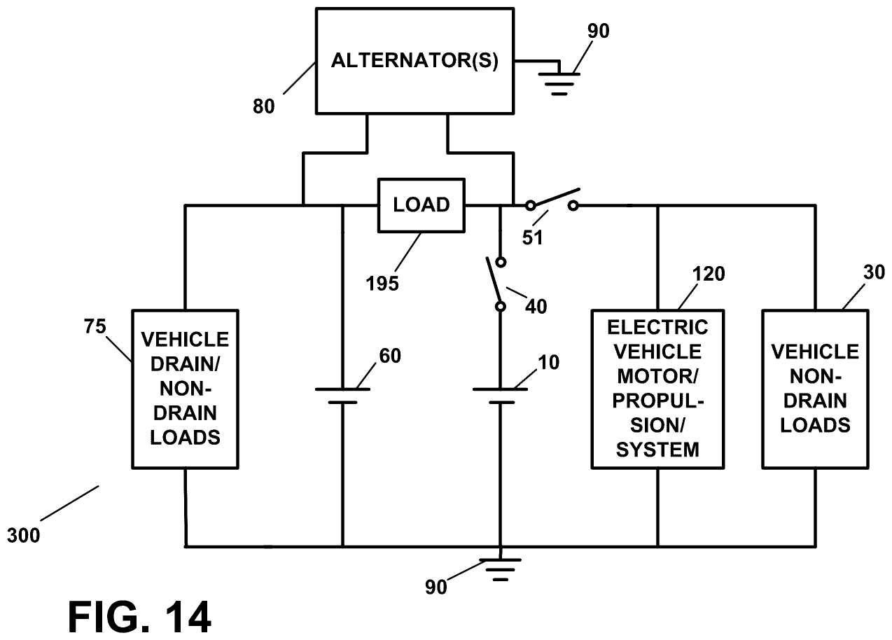

In another preferred embodiment of the apparatus 300 of FIG. 9A, the vehicle auxiliary battery 60 can be utilized to provide electrical power to the circuit portion of the apparatus 300 which is connected to the vehicle battery 10 while the vehicle battery 10 can be utilized to provide electrical power to the circuit portion of the apparatus 300 which is connected to the vehicle auxiliary battery 60. FIG. 14 illustrates another preferred embodiment of the apparatus 300 of FIG. 9A. In the embodiment of FIG. 14, the apparatus 300 can also include a voltage stabilizing load or resistor 195 (hereinafter “resistor 195” or “load 195”) which can be utilized and which can be inserted between the circuit portion of the apparatus 300 which is powered by the vehicle battery 10 and the circuit portion of the apparatus 300 which is powered by the vehicle auxiliary battery 60 in order to connect the two circuit portions together. The resistor 195 can be connected in between the positive sides of each of the vehicle battery 10 and the vehicle auxiliary battery 60, as shown in FIG. 14.

With the use of the resistor 195, electrical power can be provided from the vehicle auxiliary battery 60 to the vehicle non-drain loads 30 and/or to the electric vehicle motor/propulsion system 120, if desired, when the Power On switch 51 is in the “switch closed” state or position or in the “ON” state or position, whether or not the main cutoff switch 40 is in the “switch closed” or “ON” state or position or in the “switch open” or “OFF” state or position. When the main cutoff switch 40 is in the “switch closed” state or position or in the “ON” state or position, electrical power can also be provided from the vehicle battery 10 to the vehicle drain/non-drain loads 75, if desired. The resistor 195 serves to connect the two circuit portions together while providing a stabilizing voltage drop across same in designs wherein, or in instances when, the respective voltages of the vehicle battery 10 and the vehicle auxiliary battery 60 are not equal.

In another preferred embodiment, as well and any and/or all of the embodiments described herein, the apparatus of the present invention can be utilized in order to monitor the vehicle auxiliary battery 60 of the respective apparatus and/or the state of charge of the respective vehicle auxiliary battery 60, to detect a low charge state of the same, and/or to effectuate the recharging of the same. In yet another preferred embodiment, the apparatus of the present invention can also be utilized in order to the monitor the respective primary vehicle battery 10 or the vehicle battery 10 of the respective apparatus and/or the state of charge of the respective primary vehicle battery 10 or the vehicle battery 10, to detect a low charge state of the same, and/or to effectuate the recharging of the same.

In such a preferred embodiment, the respective apparatus can include a battery monitoring system for monitoring the respective vehicle auxiliary battery 60, for detecting a low charge state of the same, and/or for effectuating the recharging of the same. In such a preferred embodiment, the respective apparatus can also include a battery monitoring system for monitoring the respective vehicle primary battery 10 or vehicle battery 10 of the respective apparatus, for detecting a low charge state of the same, and/or for effectuating the recharging of the same. In a preferred embodiment, a battery monitoring system or any number of battery monitoring systems can be utilized to monitor each of, or both of, the respective vehicle auxiliary battery 60, to detect a low charge state of the same, and/or to effectuate the recharging of the same.

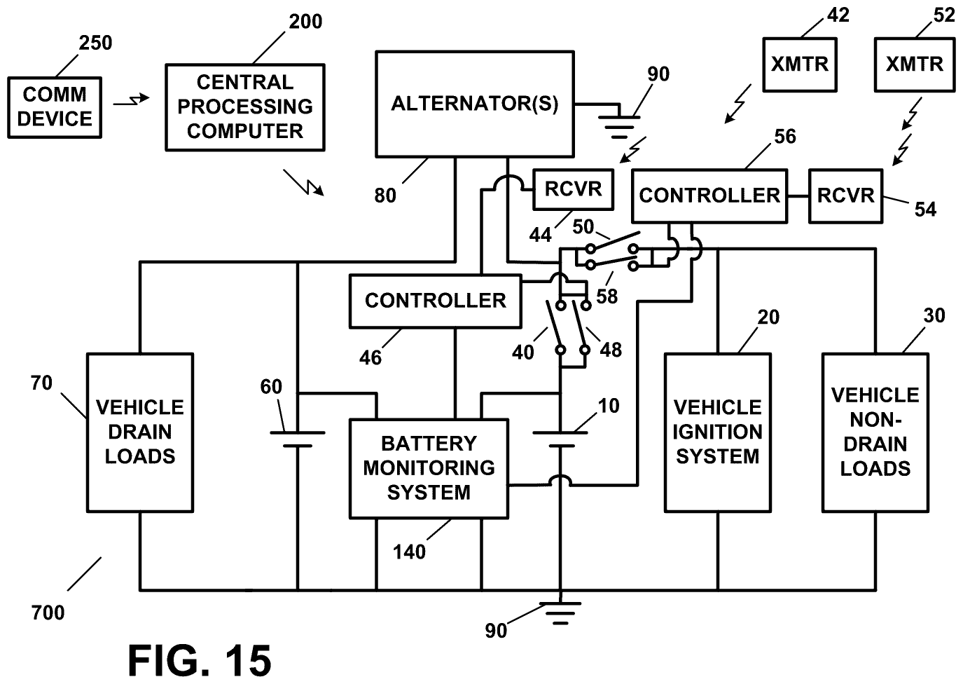

FIG. 15 illustrates another preferred embodiment of the apparatus of the present invention which is designated generally by the reference numeral 700. With reference to FIG. 15, the apparatus 700 includes all of the components of the apparatus 100 of FIG. 2 and further includes battery monitoring system 140. In a preferred embodiment, the battery monitoring system 140 includes, at the very least, a battery monitoring device (not shown), a battery monitoring computer (not shown), a receiver (not shown), and a transmitter (not shown). In a preferred embodiment, the battery monitoring computer can also include a database for storing data and/or information, including historical data and/or information, regarding the operation of, the state of charge of, and/or any other data and/or information regarding, the vehicle auxiliary battery 60 of the respective apparatus 700 and/or the primary vehicle battery 10 of the apparatus 700.

In a preferred embodiment of FIG. 15, the battery monitoring system 140 is connected to the vehicle auxiliary battery 60 as shown, to the ground 90 as shown, to the primary vehicle battery 10 as shown, to the controller 46 as shown, and to the controller 56 as shown. In a preferred embodiment, the battery monitoring system 140 can be designed, programmed, and/or configured or set-up, in order to monitor, automatically and/or otherwise, the vehicle auxiliary battery 60 and/or the state of charge of the same, on a continuous and/or on-going basis, on an intermittent basis, or in any combination of a continuous and/or on-going basis and/or an intermittent basis, to detect a low charge state of the vehicle auxiliary battery 60, and/or to effectuate a recharging of the same, such as by activating the vehicle ignition system 20 and the alternator(s) 80 by controlling an activation of, and/or a closing of any one or more of the switches 40 and/or 48 and 50 and/or 58. In a preferred embodiment, the closing of the switches 40 and/or 48 and 50 and/or 58 can, for example, activate the vehicle ignition system 20 and the alternator(s) 80 so that the alternator(s) 80 can or will recharge the vehicle auxiliary battery 60.

In a preferred embodiment, the battery monitoring system 140 of the apparatus 700 can also be designed, programmed, and/or configured or set-up, in order to monitor, automatically and/or otherwise, the primary vehicle battery 10 and/or the state of charge of the same, on a continuous and/or on-going basis, on an intermittent basis, or in any combination of a continuous and/or on-going basis and/or an intermittent basis, to detect a low charge state of the primary vehicle battery 10, and/or to effectuate a recharging of, or maintaining a charge of, the same, such as by activating the vehicle ignition system 20 and the alternator(s) 80 by controlling an activation of, and/or a closing of any one or more of the switches 40 and/or 48 and 50 and/or 58. In a preferred embodiment, the closing of the switches 40 and/or 48 and 50 and/or 58 can, for example, activate the vehicle ignition system 20 and the alternator(s) 80 so that the alternator(s) 80 can or will recharge the primary vehicle battery 10.

In a preferred embodiment, the battery monitoring system 140 of the apparatus 700 can also be designed, programmed, and/or configured or set-up, in order to generate a low battery charge message for each of the vehicle auxiliary battery 60 and/or the primary vehicle battery 10, and to transmit the low battery charge message to the communication device 250 of, used by, or associated with, the authorized user or authorized person of or for the vehicle. In a preferred embodiment, the low battery charge message can include data and/or information regarding the respective vehicle auxiliary battery 60 and/or the respective primary vehicle battery 10 for which the low state of charge is detected, the date and time of the detection of the low state of charge, and the action effectuated by the battery monitoring system 140 such as, for example, that a recharging operation has been initiated or effectuated, or is being, or is about to be, initiated or effectuated.

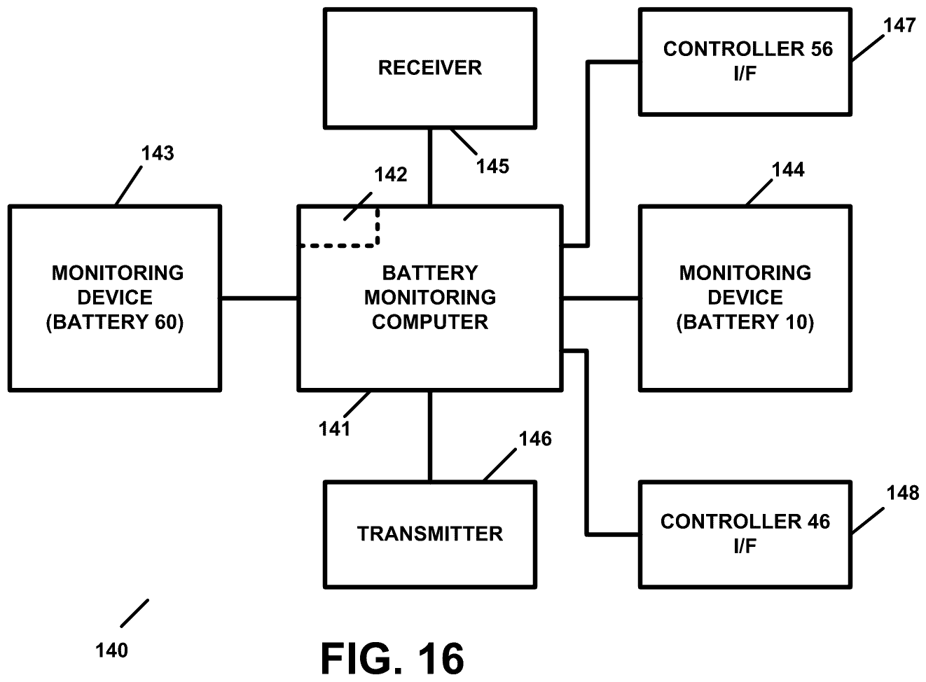

FIG. 16 illustrates a preferred embodiment of the battery monitoring system 140 of FIG. 15, in block diagram form. With reference to FIG. 16, the battery monitoring system 140 includes a battery monitoring computer 141 which includes a database 142. In a preferred embodiment, the database 142 can store information regarding the state of charge of and for each of the respective vehicle auxiliary battery 60 and/or the respective primary vehicle battery 10 as well as any data and/or information needed, required, or desired for calculating, determining, or ascertaining, the state of charge of and for each of the respective vehicle auxiliary battery 60 and/or the respective primary vehicle battery 10.

In a preferred embodiment, for each of the respective vehicle auxiliary battery 60 and/or the respective primary vehicle battery 10, the database 142 can also store data and/or information regarding the battery voltage, as well as the current flow into and/or out of, as well as the amount of charge left in, each of the respective vehicle auxiliary battery 60 and/or the respective primary vehicle battery 10. In a preferred embodiment, for each of the respective vehicle auxiliary battery 60 and/or the respective primary vehicle battery 10, the database 142 can also store data and/or information regarding the energy that flows from or out of each of the respective vehicle auxiliary battery 60 and/or the respective primary vehicle battery 10.

In a preferred embodiment, the database 142 can also store data and/or information regarding the low voltage limits or thresholds, or any stored value(s) which constitute or define a low voltage, or a low state of charge, of and/or for each of the respective vehicle auxiliary battery 60 and/or the respective primary vehicle battery 10.

With reference once again to FIG. 16, the battery monitoring system 140 also includes a monitoring device for battery 60 143 (hereinafter referred to as “monitoring device (battery 60) 143”) and a monitoring device for battery 10 144 (hereinafter referred to as “monitoring device (battery 10) 144”). In a preferred embodiment, each of the monitoring device (battery 60) 143 and/or the monitoring device (battery 10) 144 can be, or can include, any suitable battery monitoring device, and/or can be or can include any suitable or appropriate shunt-based battery monitoring device, and/or can be or can include any suitable or appropriate voltage-based battery monitoring device, and/or can be or can include any suitable or appropriate voltmeter, and/or can be or can include any suitable battery monitoring device, system, or equipment.

In a preferred embodiment, each of the monitoring device (battery 60) 143 and/or the monitoring device (battery 10) 44 can be, or can include, any suitable or appropriate device or equipment, any suitable or appropriate shunt-based battery monitoring device, any suitable or appropriate voltage-based battery monitoring device, any suitable or appropriate voltmeter, and/or any suitable or appropriate battery monitoring device, system, or equipment, which:
1) can monitor, measure, and/or determine, and/or ascertain, the energy which flows from or out of each of the respective vehicle auxiliary battery 60 and/or the respective primary vehicle battery 10; and/or
2) can monitor, measure, and/or determine, and/or ascertain, the state of charge of and for each of the respective vehicle auxiliary battery 60 and/or the respective primary vehicle battery 10, as well as any data and/or information needed, required, or desired, for calculating, determining, or ascertaining, the state of charge of and for each of the respective vehicle auxiliary battery 60 and/or the respective primary vehicle battery 10; and/or
3) can monitor, measure, and/or determine, and/or ascertain, data and/or information regarding the battery voltage, as well as the current flow into and/or out of, as well as the amount of charge left in, each of the respective vehicle auxiliary battery 60 and/or the respective primary vehicle battery 10.

With reference once again to FIG. 16, the battery monitoring computer 141 is connected to, or linked with, the monitoring device (battery 60) 143, as shown, and the battery monitoring computer 141 is connected to, or linked with, the monitoring device (battery 10) 144, as shown. In a preferred embodiment, the battery monitoring computer 141 can control and/or can monitor the operation of each of the monitoring device (battery 60) 143 and the monitoring device (battery 10) 144. In a preferred embodiment, any data and/or information obtained by, read by, monitored by, and/or measured by, each of the monitoring device (battery 60) 143 and/or the monitoring device (battery 10) 144, can be transmitted to the battery monitoring computer 141, by and/or from each of the monitoring device (battery 60) 143 and/or the monitoring device (battery 10) 144, and/or can be received, read, obtained, or measured, by and/or at the battery monitoring computer 141.

In a preferred embodiment, the battery monitoring computer 141 can be specially programmed and/or equipped to receive, request, and/or process, data and/or information obtained by, with, or at, each of the monitoring device (battery 60) 143 and/or the monitoring device (battery 10) 144. In a preferred embodiment, the battery monitoring computer 141 can also be specially programmed and/or equipped to process any data and/or information in order to determine a state of charge of the vehicle auxiliary battery 60 and/or the respective primary vehicle battery 10, to determine a low charge state for each of the vehicle auxiliary battery 60 and/or the respective primary vehicle battery 10, and/or to determine if any of the vehicle auxiliary battery 60 and/or the respective primary vehicle battery 10 needs to be recharged.

In a preferred embodiment, the battery monitoring computer 141 can also be specially programmed and/or equipped to process any data and/or information in order:
1) to determine, and/or ascertain, the energy which flows from or out of each of the respective vehicle auxiliary battery 60 and/or the respective primary vehicle battery 10; and/or
2) to determine, and/or ascertain, the state of charge of and for each of the respective vehicle auxiliary battery 60 and/or the respective primary vehicle battery 10, as well as any data and/or information needed, required, or desired, for calculating, determining, or ascertaining, the state of charge of and for each of the respective vehicle auxiliary battery 60 and/or the respective primary vehicle battery 10; and/or
3) to determine, and/or ascertain, data and/or information regarding the battery voltage, as well as the current flow into and/or out of, as well as the amount of charge left in, each of the respective vehicle auxiliary battery 60 and/or the respective primary vehicle battery 10.

In a preferred embodiment, each of the monitoring device (battery 60) 143 and the monitoring device (battery 10) 144 serve as input devices to the battery monitoring computer 141 as each of the monitoring device (battery 60) 143 and the monitoring device (battery 10) 144 monitor and obtain or collect information from their respective battery and they each provide, relay, or transmit, the data and/or information obtained or collected from their respective battery to the battery monitoring computer 141.

With reference once again to FIG. 16, the battery monitoring system 140 also includes a receiver 145 which receives, and/or for receiving, any data and/or information transmitted by or from the monitoring device (battery 60) 143 and/or by or from the monitoring device (battery 10) 144, as well as any data, information, and/or command signals, and/or any control signals and/or monitoring signals, transmitted by or from the central processing computer 200, transmitted by or from the communication device 250 of, used by, or associated with, the authorized user or authorized person of or for the vehicle, transmitted by or from the transmitter 42, and/or transmitted by or from the transmitter 52.

With reference once again to FIG. 16, the battery monitoring system 140 also includes a transmitter 146 which transmits, or for transmitting, any data and/or information, and/or commands, and/or any control signals and/or monitoring signals, to the monitoring device (battery 60) 143 and/or to the monitoring device (battery 10) 144, as well as any data, information, and/or command signals, and/or any control signals and/or monitoring signals, to the central processing computer 200, to the communication device 250 of, used by, or associated with, the authorized user or authorized person of or for the vehicle, to the receiver 44, and/or to the receiver 54.

With reference once again to FIG. 16, the battery monitoring system 140 also includes a controller 56 interface (I/F) 147 (hereinafter referred to as “controller 56 I/F 147”) which provides and/or facilitates a direct electrical connection or link, for providing and/or facilitating bi-directional communication, between the battery monitoring computer 141, and the battery monitoring system 140, and the controller 56. In a preferred embodiment, with regards to the apparatus 700 of FIG. 15, the battery monitoring system 140 and, in particular, the battery monitoring computer 141 can issue or transmit control signals and/or monitoring signals to the controller 56 via the controller 56 I/F 147 in order to effectuate the opening and/or the closing of the switches 50 and 58, in the case of the apparatus 700.

With reference once again to FIG. 16, the battery monitoring system 140 also includes an controller 46 interface (I/F) 148 (hereinafter referred to as “controller 46 I/F 148”) which provides and/or facilitates a direct electrical connection or link, for providing and/or facilitating bi-directional communication, between the battery monitoring computer 141 and the controller 46. In a preferred embodiment, the battery monitoring system 140 and, in particular, the battery monitoring computer 141, can issue or transmit control signals and/or monitoring signals to the controller 46 via the controller 46 I/F 148 in order to effectuate the opening and/or the closing of the switches 40 and 48.

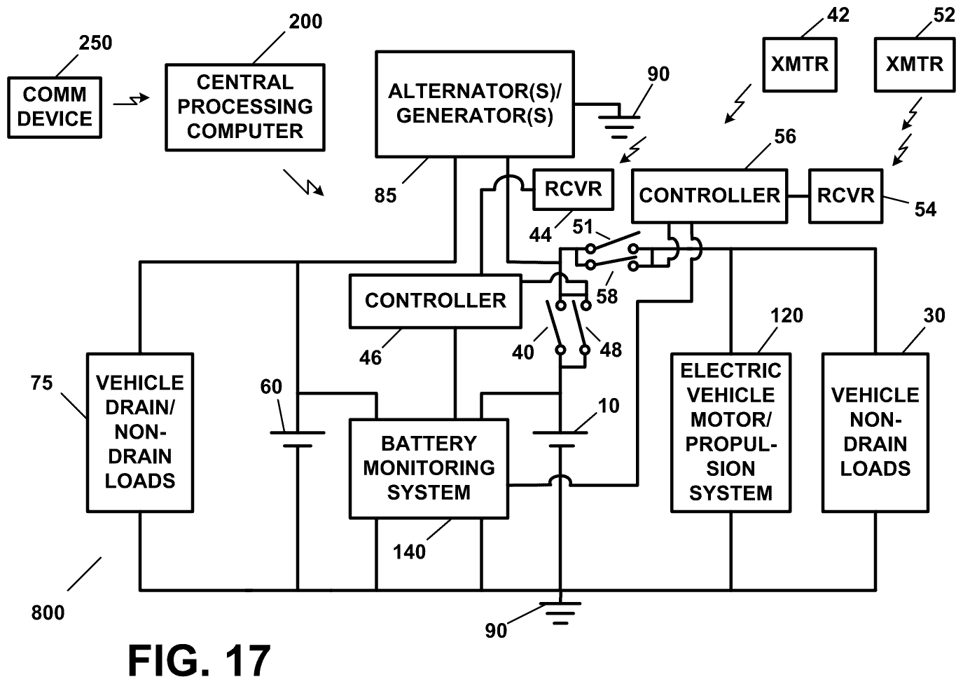

In another preferred embodiment, the battery monitoring system 140 of FIGS. 15 and 16 can also be utilized in connection with electric vehicles, all-electric vehicles, and/or hybrid vehicles. FIG. 17 illustrates another preferred embodiment of the apparatus of the present invention which is designated generally by the reference numeral 800. In a preferred embodiment, the apparatus 800 of FIG. 17 can be utilized utilized in connection with electric vehicles, all-electric vehicles, and/or hybrid vehicles.

With reference to FIG. 17, the apparatus 800 includes all of the components of the apparatus 600 of FIG. 13 and further includes the battery monitoring system 140. In the preferred embodiment of FIG. 17, the battery monitoring system 140 includes all of the components described in FIG. 16. In a preferred embodiment, the battery monitoring computer 141 can also include a database 142 for storing data and/or information, including historical data and/or information, regarding the operation of, the state of charge of, and/or any other data and/or information regarding, the vehicle auxiliary battery 60 of the respective apparatus 800 and/or the vehicle battery 10 of the apparatus 800.

In a preferred embodiment of FIG. 17, the battery monitoring system 140 of the apparatus 800 is connected to the vehicle auxiliary battery 60 as shown, to the ground 90 as shown, to the vehicle battery 10 as shown, to the controller 46 as shown, and to the controller 56 as shown. In a preferred embodiment, the battery monitoring system 140 can be designed, programmed, and/or configured or set-up, in order to monitor, automatically and/or otherwise, the vehicle auxiliary battery 60 and/or the state of charge of the same, on a continuous and/or on-going basis, on an intermittent basis, or in any combination of a continuous and/or on-going basis and/or an intermittent basis, to detect a low charge state of the vehicle auxiliary battery 60, and/or to effectuate a recharging of the same, such as by activating the electric vehicle motor/propulsion system 120 and the alternator(s)/generator(s) 85 by controlling an activation of, and/or a closing of any one or more of the switches 40 and/or 48 and 51 and/or 58. In a preferred embodiment, the closing of the switches 40 and/or 48 and 51 and/or 58 can, for example, activate the electric vehicle motor/propulsion system 120 and the alternator(s)/generator(s) 85 so that the alternator(s)/generator(s) 85 can or will recharge the vehicle auxiliary battery 60.

In a preferred embodiment, the battery monitoring system 140 can also be designed, programmed, and/or configured or set-up, in order to monitor, automatically and/or otherwise, the vehicle battery 10 and/or the state of charge of the same, on a continuous and/or on-going basis, on an intermittent basis, or in any combination of a continuous and/or on-going basis and/or an intermittent basis, to detect a low charge state of the vehicle battery 10, and/or to effectuate a recharging of, or maintaining a charge of, the same, such as by activating the electric vehicle motor/propulsion system 120 and the alternator(s)/generator(s) 85 by controlling an activation of, and/or a closing of any one or more of the switches 40 and/or 48 and 51 and/or 58. In a preferred embodiment, the closing of the switches 40 and/or 48 and 51 and/or 58 can, for example, activate the electric vehicle motor/propulsion system 120 and the alternator(s)/generator(s) 85 so that the alternator(s)/generator(s) 85 can or will recharge the vehicle battery 10.

In another preferred embodiment, the battery monitoring system 140 of the apparatus 800 can also be designed, programmed, and/or configured or set-up, in order to generate a low battery charge message for each of the vehicle auxiliary battery 60 and/or the primary vehicle battery 10, and to transmit the low battery charge message to the communication device 250 of, used by, or associated with, the authorized user or authorized person of or for the vehicle. In a preferred embodiment, the low battery charge message can include data and/or information regarding the respective vehicle auxiliary battery 60 and/or the respective primary vehicle battery 10 for which the low state of charge is detected, the date and time of the detection of the low state of charge, and the action effectuated by the battery monitoring system 140 such as, for example, that a recharging operation has been initiated or effectuated, or is being, or is about to be, initiated or effectuated.

It is important to note that the battery monitoring system 140 of FIG. 17 is the same as, and contains the same components as, the battery monitoring system 140 of FIG. 16. It is, however, important to note that the battery monitoring system 140 of the apparatus 800 of FIG. 17 can issue or transmit control signals and/or monitoring signals to the controller 56 via the controller 56 I/F 147 in order to effectuate the opening and/or the closing of the switches 51 and 58, and the battery monitoring system 140 can issue or transmit control signals and/or monitoring signals to the controller 46 via the controller 46 I/F 148 in order to effectuate the opening and/or the closing of the switches 40 and 48.

In another preferred embodiment, the apparatus 700 of the present invention can be utilized in order to monitor the state of charge of the vehicle auxiliary battery 60 so as to ensure that the vehicle drain loads 70 are not in danger of being under powered or not being powered at all. In a preferred embodiment, the apparatus 700 can be utilized to detect a low state of charge of or for the vehicle auxiliary battery 60, can generate a low state of charge alert message and can transmit the same to the communication device 250 of, used by, or associated with, the authorized user or authorized person of or for the vehicle, and/or to the central processing computer 200 so as to provide notification of and regarding the low state of charge of or for the vehicle auxiliary battery 60, and the apparatus 700 can activate the operation of the vehicle ignition system 20 and the alternator(s) 80 which alternator(s) 80 can recharge and/or at the very least maintain the charge of the vehicle auxiliary battery 60 so as to ensure that electrical power is, and continues to be, provided to the vehicle drain loads 70.

In a similar manner, in a preferred embodiment, the apparatus 700 can also be utilized to monitor and detect a low state of charge of or for the primary vehicle battery 10, can generate a low state of charge alert message and can transmit the same to the communication device 250 of, used by, or associated with, the authorized user or authorized person of or for the vehicle, and/or to the central processing computer 200 so as to provide notification of and regarding the low state of charge of or for the primary vehicle battery 10, and the apparatus 700 can activate the operation of the vehicle ignition system 20 and the alternator(s) 80 which alternator(s) 80 can recharge and/or maintain the charge of the primary vehicle battery 10.

In another preferred embodiment, the apparatus 800 of the present invention can also be utilized in order to monitor the state of charge of the vehicle auxiliary battery 60 so as to ensure that the vehicle drain/non-drain loads 75 are not in danger of being under powered or not being powered at all. In a preferred embodiment, the apparatus 800 can be utilized to detect a low state of charge of or for the vehicle auxiliary battery 60, can generate a low state of charge alert message and can transmit the same to the communication device 250 of, used by, or associated with, the authorized user or authorized person of or for the vehicle, and/or to the central processing computer 200 so as to provide notification of and regarding the low state of charge of or for the vehicle auxiliary battery 60, and the apparatus 800 can activate the operation of the electric vehicle motor/propulsion/system 120 and the alternator(s)/generator(s) 85 which alternator(s)/generator(s) 85 can recharge and/or at the very least maintain the charge of the vehicle auxiliary battery 60 so as to ensure that electrical power is, and continues to be, provided to the vehicle drain/non-drain loads 75.

In a similar manner, in a preferred embodiment, the apparatus 800 can also be utilized to monitor and detect a low state of charge of or for the primary vehicle battery 10, can generate a low state of charge alert message and can transmit the same to the communication device 250 of, used by, or associated with, the authorized user or authorized person of or for the vehicle, and/or to the central processing computer 200 so as to provide notification of and regarding the low state of charge of or for the primary vehicle battery 10, and the apparatus 800 can activate the operation of the electric vehicle motor/propulsion/system 120 and the alternator(s)/generator(s) 85 which alternator(s)/generator(s) 85 can recharge and/or maintain the charge of the primary vehicle battery 10.

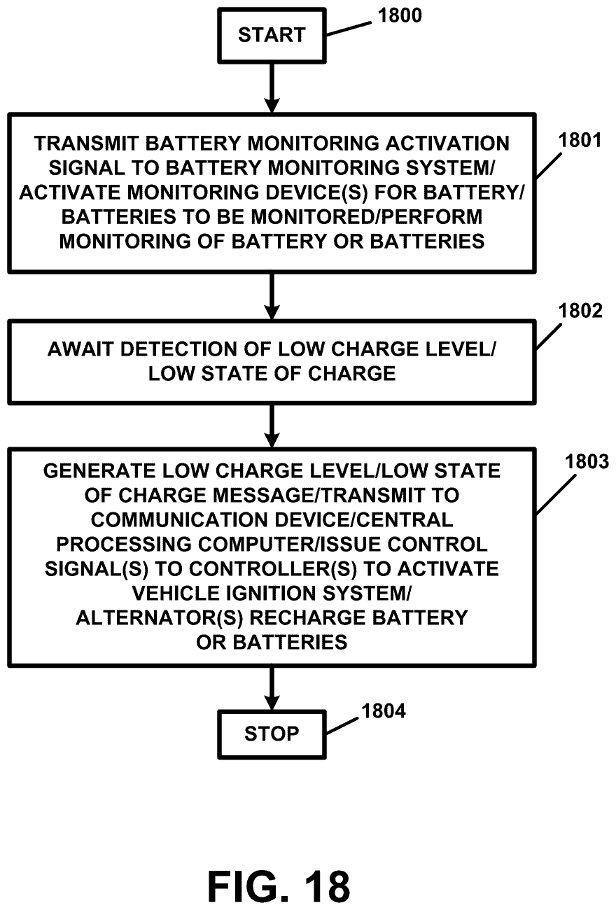

FIG. 18 illustrates a preferred embodiment method for utilizing the apparatus 700 of FIG. 15. With reference to FIG. 18, the operation of the apparatus 700 will commence at step 1800. In a preferred embodiment, at step 1801, the battery monitoring system 140 can be activated and can be made operational in monitoring the charge level or state of charge of the vehicle auxiliary battery 60 of the apparatus 700 and/or in monitoring the state of charge of the primary vehicle battery 10 of the apparatus 700. In a preferred embodiment, at step 1801, the communication device 250 can transmit a battery monitoring activation signal to the battery monitoring system 140, which battery monitoring activation signal can, at step 1801, be received by the receiver 145 and can be processed by the battery monitoring computer 141. In a preferred embodiment, at step 1801, the central processing computer 200 can also transmit a battery monitoring activation signal to the battery monitoring system 140, which battery monitoring activation signal can, at step 1801, be received by the receiver 145 and can be processed by the battery monitoring computer 141.

In a preferred embodiment, the battery monitoring activation signal can contain information for monitoring the vehicle auxiliary battery 60 only, for monitoring the primary vehicle battery 10, or for monitoring both the vehicle auxiliary battery 60 and the primary vehicle battery 10. In a preferred embodiment, the battery monitoring activation signal will contain information for monitoring the vehicle auxiliary battery 60 at the very least, so as and in order to ensure that the vehicle drain loads 70 are provided with adequate power.

Thereafter, in a preferred embodiment, the receiver 145, at step 1801, can receive the battery monitoring activation signal, and the battery monitoring computer 141, at step 1801, can obtain and process the information contained in the battery monitoring activation signal. Thereafter, at step 1801, the battery monitoring computer 141 can activate the operation of the monitoring device (battery 60) 143 and, if called for, can activate the operation of the monitoring device (battery 10) 144. Thereafter, the monitoring device (battery 60) 143, at and during step 1801, will monitor, on a continuous and/or on-going basis, the charge level or state of charge of the vehicle auxiliary battery 60. If called for, the monitoring device (battery 10) 144, at and during step 1801, will monitor, on a continuous and/or on-going basis, the charge level or state of charge of the primary vehicle battery 10.

With reference once again to FIG. 18, the operation of the apparatus 700 will proceed to step 1802. At step 1802, the apparatus 700 will await a detection of a low charge level or a low state of charge for the vehicle auxiliary battery 60 and/or, if previously called for, a detection of a low charge level or a low state of charge for the primary vehicle battery 10.

In a preferred embodiment, at and during step 1802, the battery monitoring computer 141 will obtain and/or receive, from the monitoring device (battery 60) 143 data and/or information regarding the charge level or state of charge of the vehicle auxiliary battery 60. In a preferred embodiment, the battery monitoring computer 141 can process the data and/or information obtained from the monitoring device (battery 60) 143, can determine the current charge level or current state of charge or and for the vehicle auxiliary battery 60, can compare the current charge level or current state of charge of the vehicle auxiliary battery 60 with a pre-defined or pre-specified charge level or state of charge for vehicle auxiliary battery 60, and can determine whether or not the current charge level or current state of charge is below the pre-defined or pre-specified charge level or state of charge for vehicle auxiliary battery 60. In a preferred embodiment, information regarding the pre-defined or pre-specified charge level or state of charge for vehicle auxiliary battery 60 and for the primary vehicle battery 10 can be stored in, or programmed into, the database 142 of the battery monitoring computer 141.

In a preferred embodiment, if the battery monitoring computer 141 determines that the current charge level or current state of charge of or for the vehicle auxiliary battery 60 is below the pre-defined or pre-specified charge level or state of charge for the vehicle auxiliary battery 60, then a low charge level or low state of charge is detected for the vehicle auxiliary battery 60. If called for, the battery monitoring computer 141 can also perform the above-described steps for the primary vehicle battery 10 using information obtained from the monitoring device (battery 10) 144 for the primary vehicle battery 10.

At step 1802, in a preferred embodiment, the battery monitoring computer 141 continues processing information for the vehicle auxiliary battery 60 and, if called for, the primary vehicle battery 10 until a low charge level or low state of charge is detected. In this regard, the apparatus 700, at and during step 1802, awaits a detection of a low charge level or low state of charge for the respective battery or batteries 60 or 10 being monitored. Once a low charge level or low state of charge is detected for the vehicle auxiliary battery 60 or, if called for, the primary vehicle battery 10, then the operation of the apparatus 700 will proceed to step 1803.

At step 1803, in a preferred embodiment, the battery monitoring computer 141 will generate a low charge level/low state of charge message. In a preferred embodiment, the low charge level/low state of charge message can contain data and/or information regarding the current charge level or current state of charge of or for the vehicle auxiliary battery 60 or, if called for, the primary vehicle battery 10, and the date and time of the detection of the low charge level or low state of charge.

At step 1803, the battery monitoring computer 141 will transmit the low charge level/low state of charge message to the communication device 250 and/or to the central processing computer 200. In a preferred embodiment, the low charge level/low state of charge message can serve to prompt the vehicle owner or operator to start and operate the vehicle so as to activate the alternator(s) 80 which will serve to recharge both the vehicle auxiliary battery 60 and the primary vehicle battery 10.

At step 1803, the battery monitoring computer 141 will transmit or issue a controller 46 control signal to the controller 46 via the controller 46 I/F so as to activate controller 46 to close switches 40 and 48 and the battery monitoring computer 141 will transmit or issue a controller 56 control signal to the controller 56 via the controller 56 I/F so as to activate controller 56 to close switches 50 and 58. In a preferred embodiment, the closing of switches 40 and 48 and the closing of switches 50 and 58 will activate the vehicle ignition system 20, thereby making the vehicle ignition system 20 operational. In a preferred embodiment, once the vehicle ignition system 20 becomes operational, the alternator(s) 80 of the apparatus 700 will also become operational and, in the preferred embodiment, the alternator(s) 80 will then commence recharging both the vehicle auxiliary battery 60 and the primary vehicle battery 10.

In this manner, in a preferred embodiment, a detected low charge level of low state of charge of or for either the vehicle auxiliary battery 60 or the primary vehicle battery 10, by the battery monitoring system 140, can result in the recharging of both the vehicle auxiliary battery 60 or the primary vehicle battery 10 until such time that the vehicle owner or operator can get to, and/or can attend to, the vehicle.

In the above-described manner, the apparatus 700 of the present invention can be utilized to monitor the charge level or state of charge of the vehicle auxiliary battery 60 and/or the primary vehicle battery 10, can provide notification or a low charge level or low state of charge, and can initiate and effectuate a recharging of both the vehicle auxiliary battery 60 and/or the primary vehicle battery 10 so as to provide, and/or so as to ensure the provision of, electrical power to the vehicle drain loads 70 at least until the vehicle owner or operator can get to, and/or can attend to, the vehicle, and/or until other arrangements can be made and/or servicing can be provided for the vehicle and/or for any of the components of the apparatus 700. Thereafter, the operation of the apparatus 700 will cease at step 1804.

In another preferred embodiment, the method of operation of the apparatus 700 of FIG. 18 can also be utilized in a same, a similar, and/or an analogous, manner in connection with, or in conjunction with, the apparatus 800.

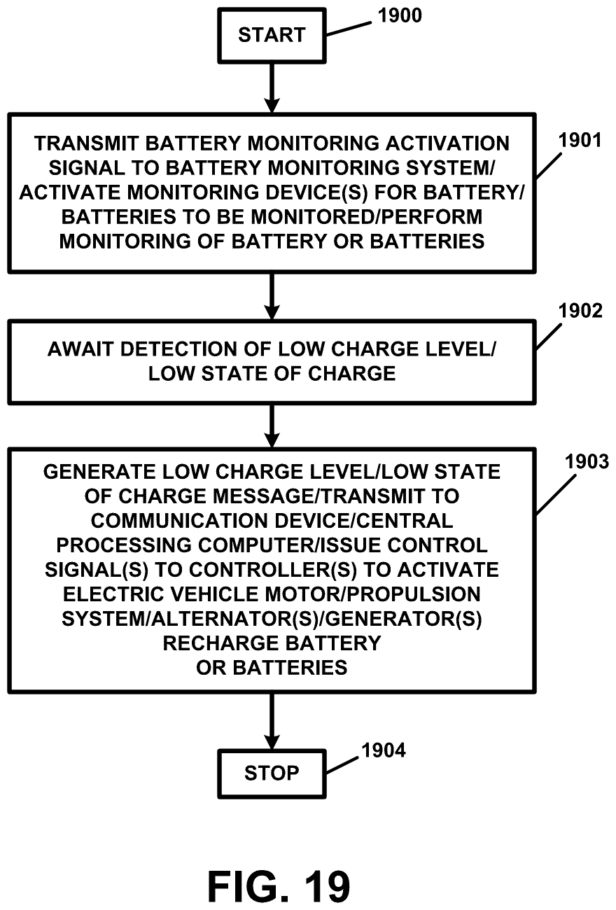

FIG. 19 illustrates a preferred embodiment method for utilizing the apparatus 800 of FIG. 17. With reference to FIG. 19, the operation of the apparatus 800 will commence at step 1900. In a preferred embodiment, at step 1901, the battery monitoring system 140 can be activated and can be made operational in monitoring the charge level or state of charge of the vehicle auxiliary battery 60 of the apparatus 800 and/or in monitoring the state of charge of the primary vehicle battery 10 or vehicle battery 10 (hereinafter referred to as “primary vehicle battery 10” or “vehicle battery 10”) of the apparatus 800. In a preferred embodiment, at step 1801, the communication device 250 can transmit a battery monitoring activation signal to the battery monitoring system 140, which battery monitoring activation signal can, at step 1901, be received by the receiver 145 and can be processed by the battery monitoring computer 141. In a preferred embodiment, at step 1901, the central processing computer 200 can also transmit a battery monitoring activation signal to the battery monitoring system 140, which battery monitoring activation signal can, at step 1901, be received by the receiver 145 and can be processed by the battery monitoring computer 141.

In a preferred embodiment, the battery monitoring activation signal can contain information for monitoring the vehicle auxiliary battery 60 only, for monitoring the primary vehicle battery 10, or for monitoring both the vehicle auxiliary battery 60 and the primary vehicle battery 10. In a preferred embodiment, the battery monitoring activation signal will contain information for monitoring the vehicle auxiliary battery 60 at the very least, so as and in order to ensure that the vehicle drain/non-drain loads 75 are provided with adequate power.

Thereafter, in a preferred embodiment, the receiver 145, at step 1901, can receive the battery monitoring activation signal, and the battery monitoring computer 141, at step 1901, can obtain and process the information contained in the battery monitoring activation signal. Thereafter, at step 1901, the battery monitoring computer 141 can activate the operation of the monitoring device (battery 60) 143 and, if called for, can activate the operation of the monitoring device (battery 10) 144. Thereafter, the monitoring device (battery 60) 143, at and during step 1901, will monitor, on a continuous and/or on-going basis, the charge level or state of charge of the vehicle auxiliary battery 60. If called for, the monitoring device (battery 10) 144, at and during step 1901, will monitor, on a continuous and/or on-going basis, the charge level or state of charge of the primary vehicle battery 10.

With reference once again to FIG. 19, the operation of the apparatus 800 will proceed to step 1902. At step 1902, the apparatus 800 will await a detection of a low charge level or a low state of charge for the vehicle auxiliary battery 60 and/or, if previously called for, a detection of a low charge level or a low state of charge for the primary vehicle battery 10.

In a preferred embodiment, at and during step 1902, the battery monitoring computer 141 will obtain and/or receive, from the monitoring device (battery 60) 143 data and/or information regarding the charge level or state of charge of the vehicle auxiliary battery 60. In a preferred embodiment, the battery monitoring computer 141 can process the data and/or information obtained from the monitoring device (battery 60) 143, can determine the current charge level or current state of charge or and for the vehicle auxiliary battery 60, can compare the current charge level or current state of charge of the vehicle auxiliary battery 60 with a pre-defined or pre-specified charge level or state of charge for vehicle auxiliary battery 60, and can determine whether or not the current charge level or current state of charge is below the pre-defined or pre-specified charge level or state of charge for vehicle auxiliary battery 60. In a preferred embodiment, information regarding the pre-defined or pre-specified charge level or state of charge for vehicle auxiliary battery 60 and for the primary vehicle battery 10 can be stored in, or programmed into, the database 142 of the battery monitoring computer 141.

In a preferred embodiment, if the battery monitoring computer 141 determines that the current charge level or current state of charge of or for the vehicle auxiliary battery 60 is below the pre-defined or pre-specified charge level or state of charge for the vehicle auxiliary battery 60, then a low charge level or low state of charge is detected for the vehicle auxiliary battery 60. If called for, the battery monitoring computer 141 can also perform the above-described steps for the primary vehicle battery 10 using information obtained from the monitoring device (battery 10) 144 for the primary vehicle battery 10.

At step 1902, in a preferred embodiment, the battery monitoring computer 141 continues processing information for the vehicle auxiliary battery 60 and, if called for, the primary vehicle battery 10 until a low charge level or low state of charge is detected. In this regard, the apparatus 800, at and during step 1902, awaits a detection of a low charge level or low state of charge for the respective battery or batteries 60 or 10 being monitored. Once a low charge level or low state of charge is detected for the vehicle auxiliary battery 60 or, if called for, the primary vehicle battery 10, then the operation of the apparatus 800 will proceed to step 1903.

At step 1903, in a preferred embodiment, the battery monitoring computer 141 will generate a low charge level/low state of charge message. In a preferred embodiment, the low charge level/low state of charge message can contain data and/or information regarding the current charge level or current state of charge of or for the vehicle auxiliary battery 60 or, if called for, the primary vehicle battery 10, and the date and time of the detection of the low charge level or low state of charge.

At step 1903, the battery monitoring computer 141 will transmit the low charge level/low state of charge message to the communication device 250 and/or to the central processing computer 200. In a preferred embodiment, the low charge level/low state of charge message can serve to prompt the vehicle owner or operator to start and operate the vehicle so as to activate the alternator(s)/generator(s) 85 which will serve to recharge both the vehicle auxiliary battery 60 and the primary vehicle battery 10.

At step 1903, the battery monitoring computer 141 will transmit or issue a controller 46 control signal to the controller 46 via the controller 46 I/F so as to activate controller 46 to close switches 40 and 48 and the battery monitoring computer 141 will transmit or issue a controller 56 control signal to the controller 56 via the controller 56 I/F so as to activate controller 56 to close switches 51 and 58. In a preferred embodiment, the closing of switches 40 and 48 and the closing of switches 51 and 58 will activate the electric vehicle motor/propulsion system 120, thereby making the electric vehicle motor/propulsion system 120 operational. In a preferred embodiment, once the electric vehicle motor/propulsion system 120 becomes operational, the alternator(s)/generator(s) 85 of the apparatus 800 will also become operational and, in the preferred embodiment, the alternator(s)/generator(s) 85 will then commence recharging both the vehicle auxiliary battery 60 and the primary vehicle battery 10.

In this manner, in a preferred embodiment, a detected low charge level of low state of charge of or for either the vehicle auxiliary battery 60 or the primary vehicle battery 10, by the battery monitoring system 140, can result in the recharging of both the vehicle auxiliary battery 60 or the primary vehicle battery 10 until such time that the vehicle owner or operator can get to, and/or can attend to, the vehicle.

In the above-described manner, the apparatus 800 of the present invention can be utilized to monitor the charge level or state of charge of the vehicle auxiliary battery 60 and/or the primary vehicle battery 10, can provide notification or a low charge level or low state of charge, and can initiate and effectuate a recharging of both the vehicle auxiliary battery 60 and/or the primary vehicle battery 10 so as to provide, and/or so as to ensure the provision of, electrical power to the vehicle drain/non-drain loads 75 at least until the vehicle owner or operator can get to, and/or can attend to, the vehicle, and/or until other arrangements can be made and/or servicing can be provided for the vehicle and/or for any of the components of the apparatus 800. Thereafter, the operation of the apparatus 800 will cease at step 1904.

In another preferred embodiment, as well as in any and/or all of the embodiments described herein, the apparatus and methods of the present invention can also be utilized in, on, and/or in connection with, and/or in conjunction with, vehicles of any kinds, types, or sizes, including, but not limited to, vehicles which require, or which may require, a driver, an operator, or a pilot, self-driving vehicles, autonomous vehicles, and/or remote-controlled vehicles, any of which vehicles can also be land vehicles, air vehicles, and/or sea vehicles or marine vehicles, of any kind, type, or size, and including, but not limited to, automobiles, cars, trucks, buses, trains, subway trains, aircraft, airplanes, jets, helicopters, drones, spacecraft, and/or satellites, and/or water vehicles or marine vehicles, boats, ships, submarines, and/or submersible vehicles, or any kind, type, or size.

In this regard, in a preferred embodiment, the apparatus and methods of the present invention can be utilized in, on, and/or in connection with, and/or in conjunction with, vehicles of any kinds, types, or sizes, including, but not limited to, vehicles which require, or which may require, a driver, an operator, or a pilot, self-driving vehicles, autonomous vehicles, and/or remote-controlled vehicles. Further, the apparatus and methods of the present invention can also be utilized in, on, and/or in connection with, and/or in conjunction with, land vehicles, air vehicles, and/or sea vehicles or marine vehicles, of any kind, type, or size. Still further, the apparatus and methods of the present invention can also be utilized in, on, and/or in connection with, and/or in conjunction with, automobiles, cars, trucks, buses, trains, subway trains, aircraft, airplanes, jets, helicopters, drones, spacecraft, and/or satellites, and/or water vehicles or marine vehicles, boats, ships, submarines, and/or submersible vehicles, or any kind, type, or size.

While the present invention has been described and illustrated in various preferred and alternate embodiments, such descriptions are merely illustrative of the present invention and are not to be construed to be limitations thereof. In this regard, the present invention encompasses all modifications, variations, and/or alternate, embodiments, with the scope of the present invention being limited only by the claims which follow.

What is claimed is:

1. An apparatus, comprising:
a first circuit, wherein the first circuit contains a first load, wherein the first load does not draw current from a first battery when the first load is not operating, and further wherein the first load comprises a vehicle ignition system or an electric vehicle motor or propulsion system of an electric vehicle, an all-electric vehicle, or a hybrid vehicle;
a first battery monitoring device, wherein the first battery monitoring device monitors a first charge level or a first state of charge of the first battery;
a second circuit, wherein the second circuit contains a second load, wherein the second load draws current from a second battery when the first load is not operating or is non-operational;
a second battery monitoring device, wherein the second battery monitoring device monitors a second charge level or a second state of charge of the second battery;
a first switch, wherein the first switch is capable of disconnecting the first battery from the first circuit;
a first controller, wherein the first controller controls the first switch;
a second switch, wherein the second switch is capable of connecting the first battery to the first circuit, and further wherein the first switch and the second switch are connected in series;
a second controller, wherein the second controller controls the second switch;
at least one recharger, wherein the at least one recharger is capable of recharging the first battery and the second battery when the first load is operating, wherein the apparatus is capable of providing electrical power to the second load when the at least one recharger ceases to operate or becomes non-operational; and
a battery monitoring system, wherein the battery monitoring system further comprises:
a battery monitoring computer, wherein the battery monitoring computer detects a first battery low charge level or first battery low state of charge, or wherein the battery monitoring computer detects a second battery low charge level or second battery low state of charge, and further wherein the battery monitoring apparatus generates a low charge level/low state of charge message, and further wherein the battery monitoring computer transmits the low charge level/low state of charge message to a communication device or to a central processing computer, and further wherein the battery monitoring computer generates and issues a first control signal, wherein the first switch is closed in response to the issuance of the first control signal, and further wherein the battery monitoring computer generates and issues a second control signal, wherein the second switch is closed in response to the issuance of the second control signal, wherein the closing of the first switch and the second switch activates or renders operational the vehicle ignition system or activates or renders operational the electric vehicle motor or propulsion system, and further wherein the at least one recharger recharges the first battery and the second battery.

2. The apparatus of claim 1, further comprising:
the first battery.

3. The apparatus of claim 1, further comprising:
the second battery.

4. The apparatus of claim 1, further comprising:
a receiver, wherein the receiver receives a third control signal transmitted from a remote control device or a wireless device, wherein the apparatus or the first controller opens the first switch in response to the third control signal.

5. The apparatus of claim 1, further comprising:
a receiver, wherein the receiver receives a third control signal transmitted from a central processing computer, wherein the signal is transmitted over the Internet or the World Wide Web to the receiver, and further wherein the apparatus or the first controller opens the first switch in response to the third control signal.

6. The apparatus of claim 1, further comprising:
a third load, wherein the third load is connected between the first circuit and a third circuit, wherein the third circuit contains the second battery, and further wherein the third load generates a circuit stabilizing voltage drop when respective voltage levels of the first battery and the second battery are not equal.

7. The apparatus of claim 1, wherein the first switch is a cut-off switch.

8. The apparatus of claim 1, wherein the second switch is a switch associated with the electric vehicle motor or propulsion system of the electric vehicle, the all-electric vehicle, or the hybrid vehicle.

9. The apparatus of claim 1, wherein the first load is an eaxle.

10. The apparatus of claim 1, wherein the first load further comprises:
a transmission or a reducer; and
a differential.

11. The apparatus of claim 1, wherein at least one electric motor of the electric vehicle motor or propulsion system is an in-wheel motor.

12. The apparatus of claim 1, wherein the first load further comprises:
an electric power control unit.

13. The apparatus of claim 1, further comprising:
a first rotating shaft, wherein the first rotating shaft is a component of an electric motor, a transmission, a reduction gear, a reducer, an eaxle, an axle, or a wheel; and
a second rotating shaft, wherein the second rotating shaft is a component of the at least one recharger,
wherein the first rotating shaft drives a rotation of the second rotating shaft.

14. The apparatus of claim 13, further comprising:
a fan belt, wherein the fan belt is attached to the first rotating shaft and the second rotating shaft, and further wherein the fan belt causes the second rotating shaft to rotate in response to a rotation of the first rotating shaft.

15. The apparatus of claim 13, further comprising:
a connecting member, wherein the connecting member is connected to each of the first rotating member and the second rotating member, and further wherein the connecting member causes the second rotating member to rotate in response to a rotation of the first rotating member.

16. The apparatus of claim 1, wherein the battery monitoring system further comprises:
the first battery monitoring device;
the second battery monitoring device;
a transmitter;
a receiver;
a first controller interface (I/F); and
a second controller interface (I/F).

17. The apparatus of claim 16, wherein the first controller interface (I/F) is connected to the battery monitoring computer and facilitates an issuance of the first control signal to close the first switch.

18. The apparatus of claim 17, wherein the second controller interface (I/F) is connected to the battery monitoring computer and facilitates an issuance of the second control signal to close the second switch.

19. The apparatus of claim 1, wherein the electric vehicle, the all-electric vehicle, or the hybrid vehicle, is a land vehicle, an air vehicle, a sea vehicle, a marine vehicle, and further wherein the electric vehicle, the all-electric vehicle, or the hybrid vehicle, is a self-driving vehicle, an autonomous vehicle, or a remote-controlled vehicle.
